(19) United States
(12) Patent Application Publication
(10) Pub. No.: US 2012/0276334 A1
(43) Pub. Date: Nov. 1, 2012

(54) Surfaces with Controllable Wetting and Adhesion

(75) Inventors: Theodore Fedynyshyn, Sudbury, MA (US); Shaun R. Berry, Chelmsford, MA (US); Lalitha Parameswaran, Billerica, MA (US)

(73) Assignee: Massachusetts Institute of Technology, Cambridge, MA (US)

(21) Appl. No.: 13/402,520

(22) Filed: Feb. 22, 2012

Related U.S. Application Data
(60) Provisional application No. 61/445,834, filed on Feb. 23, 2011.

(51) Int. Cl. B32B 3/30; H05K 1/18; B05D 5/12; B29C 59/00; B05D 5/02

(52) U.S. Cl. 428/141; 264/293; 427/256; 427/58; 264/129; 361/781

(57) ABSTRACT

Surfaces that have both micrometer- and nanometer-scale features can have controllable wetting and adhesion properties. The surfaces can be reversibly switched between states of greater and lesser hydrophobicity, and between states of greater and lesser droplet adhesion.

### CLAIM OF PRIORITY

This application claims priority to U.S. Provisional Patent Application Ser. No. 61/445,834, filed on Feb. 23, 2011, which is incorporated by reference in its entirety.

### FEDERALLY SPONSORED RESEARCH

This invention was made with Government support under Grant No. FA8721-05-C-0002 awarded by the U.S. Air Force. The Government has certain rights in this invention.

### TECHNICAL FIELD

The present invention relates to surfaces with controllable wetting and adhesion.

### BACKGROUND

Hydrophobicity is the physical property of being water-repellent; hydrophobic materials tend not to dissolve in, mix with, or be wetted by water. Hydrophilicity is the opposite property of having an affinity for water and a tendency to dissolve in, mix with, or bet wetted by water. The degree of hydrophobicity or hydrophilicity of a surface can be determined by measure the angle the water forms in contact with the surface. Water contact angles can range from close to 0° to 30° on a highly hydrophilic surface, or up to 90° for less strongly hydrophilic surfaces. If the surface is hydrophobic, the contact angle will be larger than 90°. On highly hydrophobic surfaces, water contact angles can be as high as ˜120°. Some materials, which are called superhydrophobic, can have a water contact angle of 150° or greater.

Surface texture can affect how water interacts with the surface. A droplet resting on a flat solid surface and surrounded by a gas forms a characteristic contact angle θ often called the Young contact angle. If the solid surface is rough, and the liquid is in intimate contact with the rugged or featured surface, the droplet is in the Wenzel state. If the liquid rests on the tops of the features or rugged surface, it is in the Cassie-Baxter state.

Rough superhydrophobic surfaces can be found in either the Wenzel or Cassie states. The former represents a wet-contact mode of water and rough surface, where water droplets pin the surface and have a high contact angle hysteresis. The latter represents a nonwet-contact mode, where water droplets can roll off easily, owing to low contact angle hysteresis.

### SUMMARY

A surface can be dynamically, controllably, and reversibly switched between states of greater and lesser hydrophobicity, and between states of high and low liquid adhesion.

Dual-scale surfaces can be prepared, and optionally coated with a material, e.g., a hydrophilic material or a hydrophobic material. The coated surface can be hydrophilic, hydrophobic, or superhydrophobic. For some applications, a hydrophobic or superhydrophobic can be preferred. Hydrophobic dual-scale surfaces can be more hydrophobic then otherwise similar surfaces that lack features, have only microscale features, or have only nanoscale features. Depending on the surface feature pattern, i.e., the size, shape, location, and distribution of surface features, a surface can display widely varying degrees of water adhesion.

Surface hydrophobicity can be switched in response to stimuli (e.g., electric stimuli). Switching can be repeated many times without hysteresis or substantial decreases in the extent to which hydrophobicity changes. Water adhesion properties of the surface can be also switched in response to stimuli.

In one aspect, a surface having reversibly switchable wetting and/or adhesion properties includes a plurality of microscale features arranged in a microscale pattern, where at least a portion of the microscale features include a plurality of nanoscale features arranged in a nanoscale pattern. The surface can be disposed over a substrate. The substrate can include an electrode. The substrate can further include a dielectric layer between the electrode and the surface.

The microscale pattern can be a first repeating pattern. The first repeating pattern can be a street pattern, a checkerboard pattern, a line pattern, or a bull's-eye pattern. The dimensions of the microscale features can be between 1 μm and 200 μm.

The nanoscale pattern can be a second repeating pattern. The second repeating pattern can be a line pattern, a post pattern, a hole pattern, or an isolated-post pattern. The dimensions of the nanoscale features can be between 10 nm and 3,000 nm.

When the microscale pattern is a first repeating pattern selected from a street pattern, a checkerboard pattern, a line pattern, or a bull's-eye pattern, and the dimensions of the microscale features are between 1 μm and 200 μm, then the plurality of nanoscale features can occur in a second repeating pattern, where the second repeating pattern is a line pattern, a post pattern, a hole pattern, or an isolated-post pattern, and where the dimensions of the nanoscale features are between 10 nm and 3,000 nm.

Independently, the first repeating pattern can be a line pattern, and the second repeating pattern can be a line pattern. The wetting and/or adhesion properties of the surface can be different when measured parallel or perpendicular to the line pattern.

The surface can be an electrically switchable surface. The surface can include a coating covering the surface. The coating can include a hydrophobic material, a photoswitchable material, a thermally switchable material, or a chemically switchable material.

In another aspect, a method of reversibly altering the liquid adhesion properties of a surface includes providing a surface including a plurality of microscale features arranged in a microscale pattern, where at least a portion of the microscale features include a plurality of nanoscale features arranged in a nanoscale pattern, and applying an adhesion-altering stimulus to the surface.

Applying the adhesion-altering stimulus can include altering a voltage applied to the surface, exposing the surface to light, exposing the surface to an increased or decreased temperature, or contacting the surface with an adhesion-altering composition.

In another aspect, a method of reversibly altering the liquid wetting properties of a surface includes providing a surface including a plurality of microscale features arranged in a microscale pattern, where at least a portion of the microscale features include a plurality of nanoscale features arranged in a nanoscale pattern, and applying a wetting-altering stimulus to the surface.

Applying the wetting-altering stimulus can include altering a voltage applied to the surface, exposing the surface to light, exposing the surface to an increased or decreased temperature, exposing the surface to an increased or decreased pH, or contacting the surface with a wetting-altering composition.

In another aspect, a method of making a reversibly switchable surface includes forming, on a surface, a plurality of microscale features arranged in a microscale pattern, where at least a portion of the microscale features include a plurality of nanoscale features arranged in a nanoscale pattern.

Forming can include forming, across a microscale area, a plurality of nanoscale features arranged in a nanoscale pattern, and removing a portion of the nanoscale features, where removing a portion of the nanoscale features includes forming the plurality of microscale features arranged in a microscale pattern.

The method can include covering the surface with a coating. The coating can include a hydrophobic material, a photoswitchable material, a thermally switchable material, or a chemically switchable material.

In another aspect, a system includes a substrate including an electrically conductive layer, a surface arranged over the electrically conductive layer, the surface including a plurality of microscale features arranged in a microscale pattern, where at least a portion of the microscale features include a plurality of nanoscale features arranged in a nanoscale pattern, a voltage source connected to the electrically conductive layer, and a switch between the voltage source and the electrically conductive layer, configured to controllably apply or remove voltage from the electrically conductive layer

Other features, objects, and advantages will be apparent from the description and drawings, and from the claims.

### BRIEF DESCRIPTION OF THE DRAWINGS

FIG. 1 illustrates the contact angle θ of a liquid droplet at an air/liquid/solid interface.

FIG. 2 illustrates droplets on flat and textured surfaces, and different modes of interaction between the droplet and the surface.

FIG. 3 is a schematic depiction of electrowetting of a surface.

FIGS. 4A-4F are schematic depictions of surfaces with dual-scale features.

FIGS. 5A-5G schematically illustrate fabrication of a dual-scale surface.

FIG. 6 is a graphic representation of a test mask for producing microscale features on a surface.

FIG. 7 is a graphic representation of a test mask for producing nanoscale features on a surface.

### DETAILED DESCRIPTION

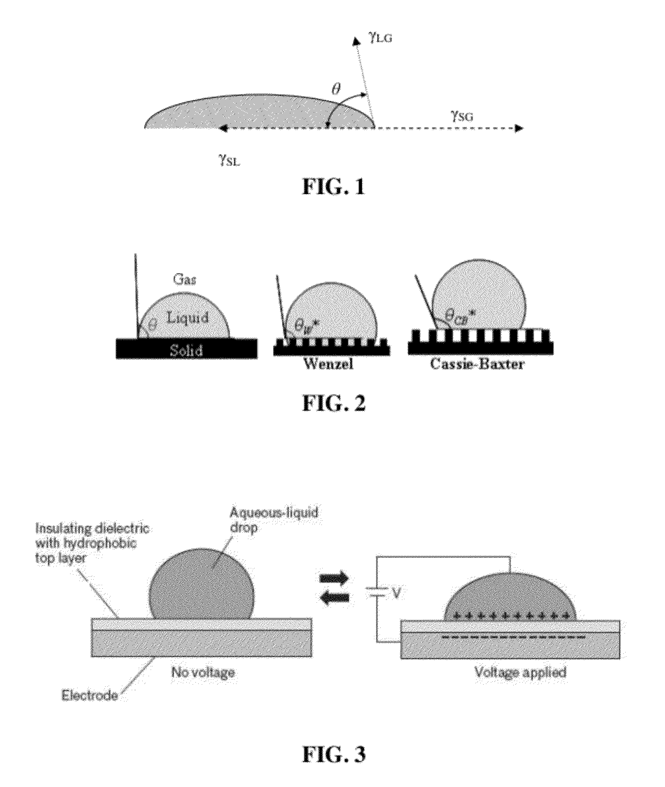

At the surface of a liquid is an interface between that liquid and some other medium. How the liquid and the medium interact depends in part on the properties of the liquid, including surface tension. Surface tension is not a property of the liquid alone, but a property of the liquid's interface with another medium. Where the two surfaces meet, they form a contact angle, θ, which is the angle that the tangent to the liquid surface makes with the solid surface. A droplet resting on a flat solid surface and surrounded by a gas forms a characteristic contact angle θ often called the Young's contact angle. Thomas Young defined the contact angle θ by analyzing the forces acting on a fluid droplet resting on a solid surface surrounded by a gas (see FIG. 1).

γ_{SG}=γ_{SL}+γ_{LG} cos θ

where γ_{SG} is the interfacial tension between the solid and gas, γ_{SL} is the interfacial tension between the solid and liquid, and γ_{LG} is the interfacial tension between the liquid and gas.

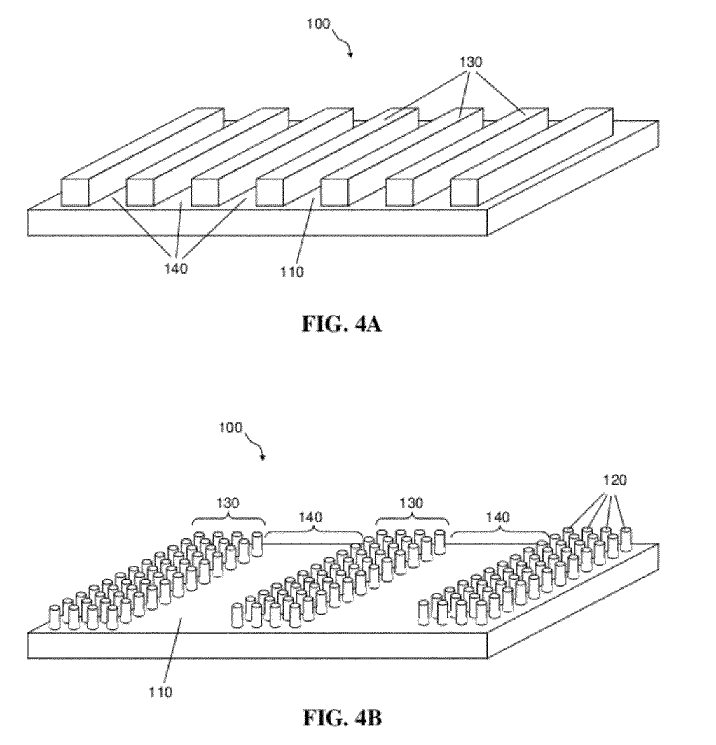

If the solid surface is rough, and the liquid is in intimate contact with the rugged or featured surface, the droplet is said to be in the Wenzel state. If instead the liquid rests on the tops of the features or rugged surface, it is said to be in the Cassie-Baxter state. Examples of these states are shown in FIG. 2.

Wenzel determined that when the liquid is in intimate contact with a microstructured surface, θ will change to θ_{W*}.

cos θ_{W*}=r cos θ

where r is the ratio of the actual area to the projected area. Wenzel's equation shows that a microstructured surface amplifies the natural tendency of a comparable featureless surface. A hydrophobic surface (one that has an original contact angle greater than 90°) becomes more hydrophobic when microstructured. In other words, its new contact angle becomes greater than the original. However, a hydrophilic surface (one that has an original contact angle less than 90°) becomes more hydrophilic when microstructured. Its new contact angle becomes smaller than the original.

Cassie and Baxter found that if the liquid is suspended on the tops of microstructures, θ will change to θ_{CB*}:

cos θ_{CB*}=φ(cos θ+1)−1

where φ is the area fraction of the solid that touches the liquid. Liquid in the Cassie-Baxter state is more mobile than in the Wenzel state.

Contact angle is a measure of static hydrophobicity, while contact angle hysteresis and slide angle are measures of dynamic hydrophobicity. Contact angle hysteresis is a phenomenon that characterizes surface heterogeneity. There are two common methods for measuring contact angle hysteresis: the tilting base method and the add/remove volume method. Both methods allow measurement of the advancing and receding contact angles. The difference between advancing and receding contact angles is called the contact angle hysteresis, and it can be used to characterize surface heterogeneity, roughness, and mobility. Heterogeneous surfaces can have domains which impede motion of the contact line. The slide angle (also known as the roll-off angle) is another dynamic measure of hydrophobicity. The slide angle, φ, is related to the advancing angle, θ_{adv}, and the receding angle, θ_{rec}, through:

$$\frac{mg sin φ}{x} = {γ}_{LG} ( cos {θ}_{rec} - cos {θ}_{adv} )$$

where g is the gravitational constant, m is the mass of the drop and x is the width of the drop.

Slide angle is measured by depositing a droplet on a surface and tilting the surface until the droplet begins to slide. Liquids in the Cassie-Baxter state generally exhibit lower slide angles and contact angle hysteresis than those in the Wenzel state.

The ability to dynamically and reversibly switch between a Wenzel state and a Cassie-Baxter state can allow control over the liquid adhesion properties of a surface. In the Wenzel state, the surface energy is increased and liquids, water in particular, adhere to the surface. In the Cassie-Baxter state, the surface energy is decreased, such that liquids, water in particular, no longer adhere and can be easily removed.

### Surfaces and Surface Features

Many surface which appear smooth to the naked eye are in fact not perfectly smooth when examined at smaller scales, i.e., at the scale of micrometers (microscale) or nanometers (nanoscale). In particular, surfaces which appear flat at the macro scale can have deviations from flatness, i.e., variations above and below an average, macro scale, “flat,” 2-dimensional surface. Thus a surface can have 3-dimensional character at the microscale and at the nanoscale.

A surface can include features which extend across both the nanoscale and the microscale. Surfaces having both microscale and nanoscale features can have increased hydrophobicity or hydrophilicity compared to flat surface, or compared to a surface having only microscale or only nanoscale features. Such a surface, having both nanoscale features and microscale features, can be referred to as a dual-scale surface. Microscale features have dimensions of approximately 1 μm or greater, 3 μm or greater, 10 μm or greater, 50 μm or greater, 100 μm or greater, 250 μm or greater, or 500 μm or greater. Microscale features can in some cases extend to greater dimensions; for example, a line-shaped feature might be several μm in width but thousands of μm in length. Despite the length extending beyond the microscale, this line-shaped feature would nonetheless be considered microscaled, because of the μm dimensions of the width.

Nanoscale features have dimensions of approximately 3 μm or smaller, 2 μm or smaller, 1 μm or smaller, or 500 nm or smaller. Nanoscale features can in some cases extend to greater dimensions; for example, a line-shaped feature might be several cm or several mm in length, or less, e.g., several nm in width up to several μm in length. Despite the length extending beyond the nanoscale, this line-shaped feature would nonetheless be considered nanoscaled, because of the nm dimensions of the width.

As is clear from the preceding description, there is not necessarily a clear dividing line between the nanoscale and microscale. Nonetheless, when microscale and nanoscale features are both present on a surface, they are desirably distinct from one another. In other words, when both present on a surface, nanoscale features are necessarily smaller than microscale features. For example, a microscale feature can have at least one dimension (e.g., height, width, depth) which is at least 2 times larger, at least 5 times larger, at least 10 times larger, or more, than does a nanoscale feature.

Features on a surface can form a pattern, e.g., a 2-dimensional pattern, which can be a regular pattern or an irregular pattern. The pattern can be a predetermined pattern, i.e., one that is selected and purposefully constructed or formed. A pattern can include sub-patterns, for example, when a number of small elements, considered together, form a larger element; or when a pattern includes two patterns interleaved or interspersed with one another. In other words, a pattern can exist across different size scales. A regular pattern can be characterized by repetition: for example, a single structure of defined size and shape, occurring at regularly spaced intervals. Such a pattern can be characterized by the size and shape of the structure, the spacing between the structures, and the geometric relationship between adjacent structures (e.g., translations, rotations, reflections, and combinations of these). A regular 2-dimensional pattern can be characterized according to which of the seventeen possible plane-symmetry groups to which it belongs.

Some exemplary patterns include street patterns, checkerboard patterns, line patterns, or bull's-eye patterns; also zig-zag, squiggly, or starburst patterns. Squiggly patterns can be any pattern that is wavy and/or twisting. A zig-zag pattern can be formed by a line or features that proceed by sharp turns in alternating directions. The corner angles can be fixed or variable within the feature. A serpentine pattern can be formed by a curved shape of features which resembles the letter s or a sine wave. A starburst pattern is a pattern of lines or features emanating from a single point. These exemplary patterns can be formed in a binary way, that is, using only two contrasting regions. In other words, they can be graphically represented using only two colors, e.g., black and white. More complex and elaborate patterns are possible, such as patterns that involve additional different contrasting regions, i.e., cannot be represent solely in black and white. It should also be noted that while these exemplary patterns can be formed using only straight lines and right angles, other forms including other angles and curved forms are possible.

A street pattern can also be referred to as a grid pattern. It can resemble a map of city blocks laid out on regularly-spaced streets which intersect only at right angles. A street pattern can be characterized by the length and width of the “city blocks,” and the width of the “streets.” A checkerboard pattern can likewise include regularly spaced blocks meeting at right angles, but with adjacent rows of blocks are offset from one another. Checkerboard patterns can be described by, independently, the length and width of the blocks, the spacing along the rows, the spacing between the rows, and the degree of offset between adjacent rows. A line pattern can include a series of parallel lines, characterized by the width of the lines and the distance between adjacent lines. A bull's-eye pattern can be formed from a series of concentric shapes, e.g., concentric circles, squares, or other shapes. The bull's-eye can be described by the width of the lines forming the sides of the squares, and the spacing between one square and the next smaller square. A bull's-eye pattern can be found in the context of a larger pattern: for example, a checkerboard pattern can be formed in which every other square includes a single bull's-eye.

Other patterns include post patterns, isolated-post patterns, hole patterns, or isolated-hole patterns. A post pattern can include posts arranged at every point on a regular grid. The post can be a vertical column with a desired cross-sectional shape, such as circular, elliptical, triangular, square, hexagonal, or any other regular or irregular shape. In a post pattern, the distance between adjacent posts can be similar or the same as the size of the posts. An isolated-post pattern can resemble a post pattern but with greater spacing between adjacent posts. For example, the spacing between posts can be a multiple of the size of the posts. A hole pattern can resemble the inverse of a post pattern. Where a post pattern can include vertical columns rising above a nominal baseline surface, a hole pattern can include vertical depressions receding below a nominal baseline surface. Again, the cross-section of the depression can be any desired shape. The spacing between adjacent holes can be similar or the same as the size of the holes. In an isolated-hole pattern, the spacing can be a multiple of the size of the holes.

Features on a surface can be oriented. In other words, the features can be aligned or distributed in an anisotropic fashion, providing directionality to the surface. For example, when a surface includes multiple line features, the lines can be all be parallel, thus defining two directions across the surface: a parallel or “with the lines” direction, and a perpendicular or “across the lines” direction. Other orientations of features are possible. Wetting properties can thereby take on directionality as well, such that the properties differ according the alignment of liquid droplets with respect to the surface features.

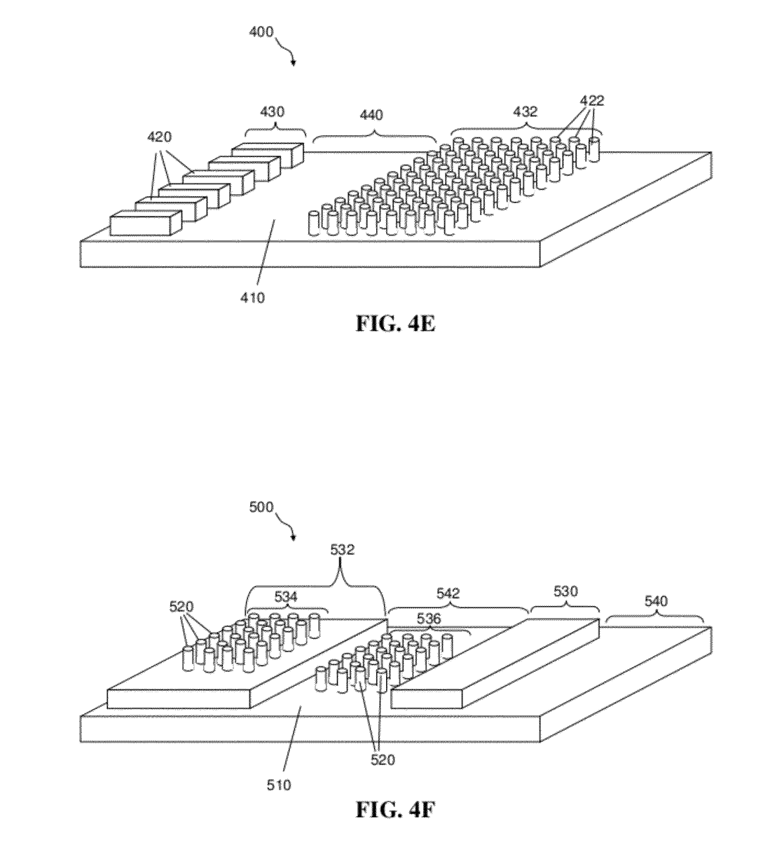

With regard to FIG. 4A, article 100 includes surface 110. Surface 110 can be a dual-scale surface, i.e., having both nanoscale and microscale features. Arranged on surface 110 are microscale features 130 and 140, a pattern of elevations 130 against a background surface 140. Alternatively, features 130 and 140 may be considered as depressions 140 in a background surface 130; the designation of features as elevations or depressions is arbitrary. The point is that features 130 and 140 have distinct three-dimensional character at the microscale, even if at the macro scale (e.g., that which is easily sensed and appreciated by a person unaided by technology such as a microscope) surface 110 is smooth, i.e., lacks any features appreciable to the unaided eye or unaided touch.

Features 130 and 140 can have any desired pattern on surface 110. The pattern can be a regular pattern or an irregular pattern. The pattern can include lines, planes, curves, posts, angles, geometric shapes (e.g., circles, squares, triangles, hexagons, etc., which may be outlines or filled shapes), zigzags, squiggly, starburst, or other configurations. In some cases, the pattern is a repeating pattern. The repeating pattern can include simple features repeated at regular intervals. Some such patterns include parallel lines, checkerboards, or grids.

FIG. 4B illustrates a portion of the article of FIG. 4A at greater magnification. In FIG. 4B it becomes apparent that surface 110 includes nanoscale features 120. Nanoscale features 120 are depicted as posts, although it is to be understood that nanoscale features 120 can have any desired shape, including lines, planes, curves, posts, angles, geometric shapes (e.g., circles, squares, triangles, hexagons, etc., which may be outlines or filled shapes), zigzags, or other configurations. On surface 110, there are areas where nanoscale features 120 are present and other areas where nanoscale features 120 are absent. On surface 110, microscale features 130 and 140 are in fact areas where nanoscale features 120 are present (130) or absent (140).

FIG. 4C depicts article 200 having surface 210. Surface 210 includes nanoscale features 220, shown here as parallel lines. Nanoscale features 220 are present in regions 230 and absent from regions 240. Thus regions 230 and regions 240 constitute microscale features on surface 210. Regions 230 and 240 are in the form parallel lines, in this case parallel with the lines of nanoscale features 220. In contrast, in FIG. 4D, article 300 has surface 310, on which nanoscale lines 320 are perpendicular to microscale lines 330 and 340.

In FIG. 4E, article 400 has surface 410 on which nanoscale and microscale features are found. Again, nanoscale features are grouped into microscale areas, which constitute microscale features. On surface 410, two types of nanoscale features are present: lines 420 and posts 422. Lines 420 are grouped into a first microscale feature 430, while posts 422 are grouped into a second microscale feature 432. Microscale features 430 and 432 are separated by a further microscale feature 440, which is characterized by the absence of nanoscale features.

In FIG. 4F, article 500 has surface 510 on which nanoscale and microscale features are found. FIG. 4F illustrates an embodiment in which the microscale features 530 and 540 are not formed by the presence or absence of nanoscale features. Instead microscale feature 530 is shown as a solid elevation and microscale feature 540 is shown as a depression (again, the designations “elevation” and “depression” are arbitrary). Surface 510 also includes microscale features 532 and 542, which are, similarly, a solid elevation and a depression, respectively. Unlike microscale features 530 and 540, however, microscale features 532 and 542 are further elaborated by the presence of additional microscale features 534 and 536. Microscale feature 534 is a group of nanoscale features 520 (here shown as posts) arranged on solid elevation 532. Microscale feature 536 is a group of nanoscale features 520 (also shown as posts) arranged in depression 542.

As described above, it is know from the work of Wenzel and Cassie that microscaled features on surfaces increase the hydrophobicity of the surface relative to a flat surface. A combination of nano- and micro-scaled features can lead to further increases in the hydrophobicity of a surface. For example, depending on the material composition of the surface, a dual-scale surface can have a water contact angle which is larger than that of a comparable flat surface by 30° or more, 40° or more, or 50° or more. A dual-scale surface can have a water contact angle which is larger than that of a comparable single-scale featured surface (i.e., one having only microscale features or only nanoscale features) by 10° or more, 20° or more, or 30° or more.

Dual-scale surfaces can also offer improvements over either flat or single-scale surfaces in terms of switchable wetting and/or adhesion behavior (switchable, e.g., in response to electric, thermal, chemical, or photo stimuli, such as electrowetting). Flat (i.e., featureless) surfaces and surfaces having only microscale features give reversible electrowetting, where the difference between electrowet and recovered contact angles range from 20° to 40°. Many surfaces having only nanoscale features do not exhibit reversible electrowetting; instead they show little to no recovery of the initial contact angle. Dual-scale surfaces, on the other hand, can provide greater differences between electrowet and recovered contact angles, such as 20° or greater, 40° or greater, 50° or greater, 60° or greater, 70° or greater, or 80° or greater.

The surface can be made of any material. In order to facilitate surface modification, the surface material can include hydroxyl groups, either as —OH groups or in some form that can be converted to —OH groups. Materials that have or can be treated to provide —OH groups include metal oxides, metal hydroxides, metal halides, or certain polymers (e.g., a poly(vinyl alcohol) or a poly(acrylate ester)).

In some cases, it can be preferable that the material have a surface partially composed of or including a metal oxide, metal hydroxide, or metal halide. A metal oxide surface can contain hydroxide functionalities either innately or through a treatment to partially hydrolyze the metal oxide. For example, the surface can include silicon dioxide, where surface silicon atoms can be found having exposed hydroxide groups. Similarly, a metal halide can also contain hydroxide functionalities either innately or through a treatment to partially hydrolyze the metal halide. Organic (i.e., carbon based) surfaces can also be employed. Such organic surfaces can preferably include a hydroxide moiety either present or in latent form (e.g., as a salt or an ester).

In some cases, the surface can be a surface of a silicon wafer. A silicon wafer can be provided with a number of different materials as the ultimate surface layer. The ultimate surface layer can be silicon, native oxide on silicon, silicon dioxide, silicon nitride, a metal oxide, a polymer, or any surface that has hydroxyl groups present or can have hydroxyl groups attached to that surface.

### Surface Modification and Coatings

The properties of the surface as regards water can be influenced by modifying or coating the surface. For example, a coating of a hydrophobic material can increase the hydrophobicity of a surface compared to a similar but uncoated surface. Such modification can be accomplished by depositing a material (e.g., an organic material such as a polymer) on the surface. Depositing the material preferably includes conformally coating the surface. A conformal coating means that all surface features are coated. For example, if a surface is not flat but includes vertical projections or depressions, the vertical walls of those features are also covered by a conformal coating. In general, coatings are more likely to be conformal when they are thin. Therefore, a coating can have a thickness of less than 250 nm, less than 50 nm, or less than 20 nm. When nanoscale features are present, it can be important for coatings to be thin. Otherwise, the dimensions of the nanoscale features may become altered by the presence of the coating.

Material can be applied to the surface in a number of ways, including, for example, spin-coating or dip-coating.

One method to modify the surface of a material is to graft a polymer onto the surface of that material. The surface can be made more or less hydrophobic depending on the nature of the surface and the grafted polymer. Graft polymerization, in which a radical or ionic initiator produces surface radical or ions, can be used for grafting. These a radicals or ions react with monomers and in a step wise fashion lead to polymer growth with the polymer covalently attached to the surface at the point of polymer initiation. A second method of grafting involves a preformed polymer which is coated or adsorbed onto a surface. This coated polymer is heated to a sufficient temperature to undergo thermally induced bond formation with the surface, leading to polymer attachment or grafting directly to the surface. The latter technique can be used to form polymer brushes on surfaces. A grafted polymer can be a highly conformal coating, and therefore can be a desirable coating.

One class of polymers that are useful for thermal grafting are acrylate- and methacrylate-based polymers. Non-limiting examples of these include acrylic acid, sodium acrylate, methacrylic acid, sodium methacrylate, propylacrylic acid, methyl methacrylate, ethyl methacrylate, n-propyl methacrylate, n-butyl acrylate, n-butyl methacrylate, isobutyl methacrylate, s-butyl methacrylate, t-butyl acrylate, t-butyl methacrylate, cyclohexyl methacrylate, 2-ethyl hexyl acrylate, neopentyl acrylate, n-octyl acrylate, n-nonyl acrylate, lauryl methacrylate, trifluoroethyl methacrylate, 2-hydroxylethyl acrylate, 2-hydroxylethyl methacrylate, 2-hydroxypropyl methacrylate, 2-pyranoxy ethyl methacrylate, 1-ethoxyethyl methacrylate, tetrahydrofurfuryl methacrylate, N,N-dimethyl amino ethyl methacrylate, bipyridylmethyl acrylate, acrylamide, N,N-dimethyl acrylamide, N-isopropyl acrylamide, N,N-dimethylaminoethylmethacrylate, or acrylonitrile polymers.

A second class of polymers that can be useful for thermal grafting are ethylenic based polymers. Non-limiting examples of these include polymers of ethylene, butadiene (by 1,2 addition), butadiene (by 1,4 addition), isobutylene, or isoprene. A third class of polymers that can be useful for thermal grafting are styrenic based polymers. Non-limiting examples of these include polymers of styrene, α-methylstyrene, t-butyl styrene, t-butoxystyrene, 4-hydroxyl styrene, 4-methyoxystyrene, 4-aminomethylstyrene, p-chloromethyl styrene, 4-styrenesulfonic acid, 2-vinyl naphthalene, 2-vinylpyridine, 4-vinylpyridine, N-methyl 2-vinyl pyridinium iodide, or N-methyl 4-vinyl pyridinium iodide. A fourth class of polymers that can be useful for thermal grafting are siloxane based polymers. Non-limiting examples of these include polymers of dimethylsiloxane, diphenyl siloxane, or methyl phenyl siloxane. A fifth class of polymers that can be useful for thermal grafting are fluorocarbon based polymers. Non-limiting examples of these include Teflon, Teflon AF, Teflon FEP, Teflon FFR, Teflon NXT, Teflon PFA, Teflon PTFE, Tefzel ETFE, Zonyl PTFE, CYTOP Type A, CYTOP Type M, or CYTOP Type S polymers.

A second method to modify the surface of a material in a conformal manner is through the use of plasma polymerization. In plasma polymerization, a plasma source generates a gas discharge that provides energy to activate or fragment a gaseous or liquid monomer to initiate polymerization. Plasma polymerization can be used to deposit polymer thin films. The chemical composition and structure of the resulting thin film can be vary widely depending on the monomer type and the energy density per monomer. Typically, the plasma polymer is produced from either a fluorocarbon plasma, a hydrocarbon plasma, or a mixed fluorocarbon/hydrocarbon plasma, and optionally hydrogen gas. Fluorocarbon plasma polymers are typically produced from the plasma polymerization of a fluorocarbon material of the general chemical formula CₓH_{y}F_{z} or CₓF_{z}, optionally in the presence of a hydrogen source, where x is and integer from 1 to 20 and/or y and/or z together satisfy the valence of the fluorocarbon. The source can be hydrogen gas, a hydrocarbon, or a hydrofluorocarbon (e.g. of the formula CₓH_{y}F_{z}). Hydrocarbon plasma polymers are typically produced from the plasma polymerization hydrocarbon material of the general formula CₓH_{y}. Non-limiting examples of gasses or liquids employed to make plasma polymers are CHF₃, CH₂F₂, C₂HF₅, C₂H₂F₄, C₂H₃F₃, CF₄, C₂F₄, C₂F₆, C₃F₆, C₄F₈, C₄F₁₀, C₅F₁₂, C₆F₁₄, C₇F₁₆, CH₄, C₂H₆, C₂H₄, C₂H₂, C₃H₈, C₃H₆, C₃H₄, C₄H₁₀, C₄H₈, C₄H₆, or H₂.

Another method to surface modify materials is silicon based coupling materials such are aryl or alkyl substituted silanols, silyl alkanols, or silyl halides. The surface modifying agent can include a coupling region containing a silicon atom bonded to at least one hydrolyzable moiety, optionally a spacer, and an active region. If no spacer region is employed, the active region can be directly attached to the silicon. The silicon atom is also typically substituted with three groups which can be identical or different, provided that one group is hydrolyzable during the surface modification reaction. Hydrolyzable groups can be, but are not limited to —H, halo, hydroxy, alkoxy, NR₂, SiR₃, NCO, or OCOR, in which R is H, alkyl, alkenyl, alkynyl or aryl. Such modification can use a silicon-containing surface modifying agent of formula (I):

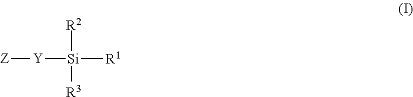

wherein

R¹ is —H, halo, hydroxy, —R⁴, —OR⁴, —N(R⁴)₂, —Si(R⁴)₃, —NCO, —CN, —OC(O)R⁴, or is —Y—Z.

Each of R² and R³, independently, is alkyl, alkoxy, haloalkyl, or haloalkoxy.

M is a metal ion.

each R⁴, independently, is —H, alkyl, vinyl, aryl, haloalkyl, halovinyl, or haloaryl.

Y is a bond, alkylene, alkenylene, or arylene.

Z is —H, halo, hydroxy, alkyl, vinyl, aryl, haloalkyl, halovinyl, haloaryl, —OR⁵, —N(R⁵)₂, —Si(R⁵)₃, —NCO, —CN, —OC(O)R⁵, —NHC(O)R⁵, —P(R⁵)₂, —P(R⁵)OR⁵, —P(OR⁵)₂, —SR⁵, —SSR⁵, —SO₂R⁵, or —SO₃R⁵.

Each R⁵, independently, is —H, alkyl, vinyl, aryl, haloalkyl, halovinyl, or haloaryl.

The surface can be modified with any number and any degree of surface modifying agents. The surface can also be modified with more than one type of surface modifying agent by attaching the agents either sequentially or concurrently.

In some embodiments, R², R³, R⁴, or R⁵ is an alkyl group or a halo-substituted alkyl group, e.g., a partially or fully fluorinated alkyl group. These materials can be preferred for electrically activated switching. In some embodiments, R⁵ can include an ethylenic double bond or a diazo double bond; these materials can be preferred for photo-activated switching.

A surface can be modified with any number and with any degree of surface modifying agents. A surface can also be modified with more then one type of surface modifying agent by attaching the agents either sequentially or concurrently. It can be advantageous to modify a surface with more then one type of surface modifying agent.

The surface modifying material can be attached to the surface by a variety of methods. In one method, a substrate having a surface to be modified can be immersed directly in the surface modifying material (i.e., where the surface modifying material is in its neat form). Alternatively, the substrate can be immersed directly in a solution of the surface modifying material. The solvent can be any solvent that dissolves the surface modifying material. If a solvent is employed, it can be preferred that the amount of surface modifying material is less than 10%, less than 1%, or less than 0.1% of the weight of the solution. Preferably the solvent employed does not react with the substrate or surface modifying material. Rather than immersion, the surface modifying material can also be spin cast either neat or in solution onto the substrate. In another method, the surface modifying material can be vaporized and the vapor placed in contract with the substrate.

### Switchable Surfaces

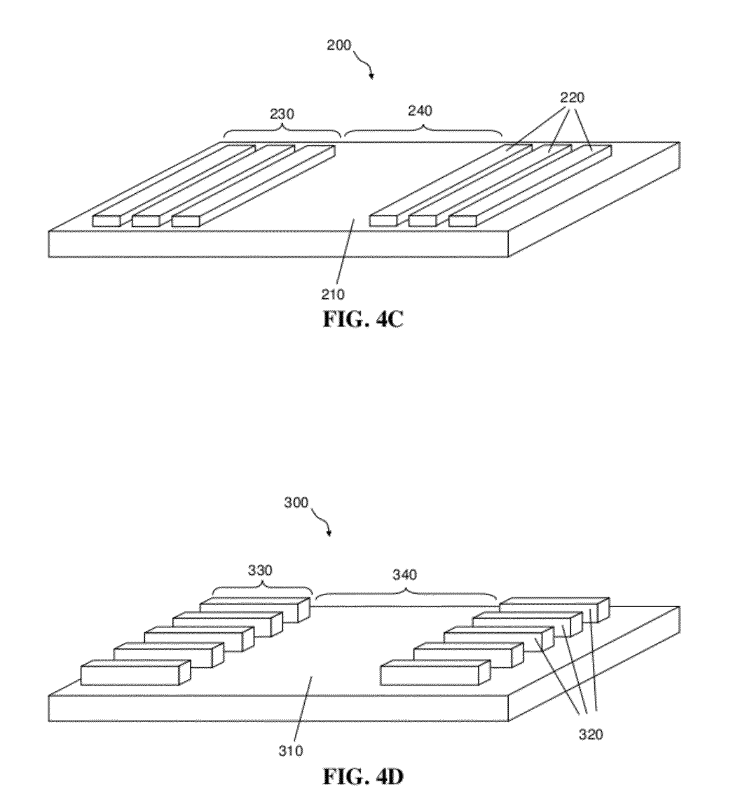

Surfaces can be made which have switchable wetting and/or adhesion properties. Methods for switching surface properties include electrical switching, electrochemical switching, photoswitching, thermal switching, or chemical switching. See, e.g., Gras, S. L. et al., ChemPhysChem 2007, 8, 2036-2050, which is incorporated by reference in its entirety. For example, a hydrophobic surface can be switched to a less hydrophobic or even hydrophilic state by application of a voltage. The change in wetting properties between the more hydrophobic state and the more hydrophilic state, measured by water contact angles can be 20° or greater, 40° or greater, 50° or greater, 60° or greater, 70° or greater, or 80° or greater. In a typical electrowetting arrangement, an aqueous liquid drop is in contact with an insulating dielectric material having a hydrophobic surface. The hydrophobic surface has contract angle defined by the properties of the liquid and solid surface. In the presence of an applied electric field, the droplet is pulled down toward the electrode, reducing the macroscopic contact angle and increasing the droplet contact area as seen in FIG. 3.

Additional examples of surface switching can occur when chemical transformations on a surface are induced by electrical, photolytic, magnetic, ionic, or thermal stimuli. These transformations can occur as the result of, for example, isomerization of a chemical moiety. Examples of isomerization are the photolytic or thermally induced cis/trans interconversion of diazo or ethylenic double bonds. The geometric changes that occur in the molecule as a result of the cis/trans interconversion can change the surface energy of the solid surface and thus the hydrophobicity of the surface. Such changes can be reversible and exhibit no hysteresis. See, e.g., Ichimura, K., et al., Science 2000, 288, 1624; L. M. Siewierski, et al., Langmuir 1996, 12, 5838; T. Seki, et al., J. Phys. Chem. B 1998, 102, 5313; T. Seki, et al., Polym. J. 1999, 31, 1079; T. Seki, et al., Macromolecules 1997, 30, 6401; and T. Seki, et al., J. Phys. Chem. B 1999, 103, 10338, each of which is incorporated by reference in its entirety.

Other examples of geometric changes that results in changes in the surface energy of the solid surface can occur in response to electrical stimuli in which the geometry of the surface transitions between straight (hydrophilic) and bent (hydrophobic) molecular conformations. See, e.g., J. Lahann, et al., Science 2003, 299, 371, which is incorporated by reference in its entirety. Surfaces can also respond to changes in ionic concentrations for example by the introduction of acids, bases, or metal ion. These changes can induce conformational changes or ionize of surface attached moieties, which in turn alters surface hydrophobicity. Surfaces can also undergo changes in hydrophobicity in response to magnetic fields. These changes are especially pronounced in fluids containing magnetic particles such as ferrofluids.

### Sample Collection and Recovery

One application of this technology is in the area of biological sample collection and recovery. Biological assays are widely used to analyze, identify and verify the presence and composition of biological materials, in areas as diverse as medical diagnostics, food testing, biological and chemical defense, and forensics. The performance of these assays is contingent on effective sample collection methods to transfer target material from the sampling site to the analysis instrument. Swabbing, using cotton or synthetic collection material for the swab tip, is one of the most widely used methods for microbiological examination of surfaces. However, there are problems associated with swabbing, stemming from the often strong, irreversible adherence of the sample to the porous swab collection material. Conventional swabbing suffers from incomplete sample collection and recovery and often requires multiple washes of the swab, resulting in recovered target that is highly diluted. Assay performance is a function of sample collection, recovery, preparation and removal of assay inhibitors, and analysis sensitivity. Much attention has been devoted to improvements in assays, but significant improvements to overall assay performance can be obtained by improving sample collection and recovery. Typically, at most 50% of the target is collected onto the swab, and only 20-40% of that collected material is recovered, often in a buffer volume much larger than that required by the analytical assay. Complete recovery of the target in a volume reduced by one or two orders of magnitude can effectively increase test sensitivity a hundredfold, without any improvements to the assay itself. Even a modest gain in target recovery or reduction in dilution would be considered a significant achievement.

A surface having dynamically switchable surface properties (e.g., hydrophobicity, adhesion, or both) can provide enhanced sample collection and enhanced sample recovery from a sampling tool. In use, for example, the sampling surface can be hydrophobic or superhydrophobic and set to a state in which the surface strongly adheres water. In this adherent state, the sampling surface can efficiently collect samples, e.g., aqueous samples, including aqueous biological samples. After sample collection has been completed, the sampling surface can be positioned so as to deliver the sample to, e.g., a sample holder, an analysis instrument, or other location where a sample is to be delivered. The sampling surface can then be switched to a non-adherent state, such that adhered samples are repelled from the surface and delivered to the desired location. Delivery can occur without the need for sample dilution or washing of the sampling surface.

### Liquid Transport

Surfaces having microscale or nanoscale features are known in nature; examples include the surfaces of lotus leaves, rose petals, and beetle backs. The Namib desert beetle has a microstructured surface that enhances nucleation of water droplets from vapor, and guides the droplets down the beetle's back to be collected. In the case of the beetle, the droplet transport is primarily gravity driven, with no explicit in-plane directionality provided by the microscale features.

With engineered surfaces, droplet adhesion can be enhanced in one direction preferentially over another based on the design of the nanostructure. Switchable adhesion surfaces can be used to create channels that can adhere droplets, and then be switched so as to preferentially force the droplets in a preferred direction, thus transporting a liquid across a surface. This concept can be readily applied to existing microfluidic devices, such as those in development for clinical diagnostics assay, to control and enhance transport of aqueous reagents and samples.

### Low-Adhesion Bandages

Burn bandages serve multiple purposes, including protection against infection, absorption of draining fluids, and provision of physical comfort. Conventional gauze bandages must be absorbent to remove drainage fluids, but stick to burn wounds. When gauze bandages are removed (as they must be, sometimes on a daily basis), they can cause extreme pain and additional damage to the wound site. Engineered switchable adhesion surfaces can enable the development of bandages that can be removed with less sticking and therefore reduced pain and tissue damage, simply by switching the state of the bandage from adhesive to nonadhesive. Additionally, with a suitable surface structure design, drainage fluid can be collected and diverted away from the wound to a secondary absorbent layer that is part of the bandage, but not in contact with the wound. The bandage can also controllably deliver medications to the wound by controlling liquid transport to and from the wound surface via switching of hydrophobic and hydrophilic regions of the bandage surface.

### Active Filters

Current passive physical filtration technology has at its heart a series of physical channels through which fluid flows; particles in the fluid pass through or are held back, depending on their sizes relative to the pore size of the filter. They are rarely reusable and frequently suffer from clogging, which causes variable performance degradation and the need for regular changes. An “active” filter is one in which the porosity of the filter can be controllably modulated. An engineered switchable adhesion surface can provide this capability. Thus an active filter can include a series of pores which contain engineered surface structures. In this way the pores can be switched between more hydrophobic and more hydrophilic states. In a more hydrophobic state, the pore can be effectively closed, whereas in a more hydrophilic state it can be open, thereby modulating the effective porosity of the filter. Additionally, such a filter can be self-cleaning. When particles become trapped in pores, the pores can be set to the more hydrophobic state thereby forcing liquid (and the suspended particles) out of the pores. The filter can then be flushed, sweeping away any particles that are suspended in the liquid.

### EXAMPLES

### Experimental

Equipment used included the following: Canon FPA 3000 iW i-line stepper; Canon FPA-3000 EX4; Lam Research Autoetch590; Lam Research Rainbow4500; Plasmatherm ICP Bosch “Versalok-700”; Novellus 372M; Mattson Aspen; and MRL Industries Cyclone 830. Polydimethysiloxane (PDMS) 1000 cSt was purchased from Gelest. Teflon AF (TAF) Type 1601 was purchased from DuPont. CYTOP (CYTOP) Type 809M was purchased from Bellex International Corporation.

Featured surfaces (whether microscale only, nanoscale only, or dual-scale) were prepared on a 150 mm diameter silicon wafer. There were 20 different nanoscale patterns and 21 different microscale patterns prepared on each wafer. The different microfeatures were patterned in a 20 mm×25 mm area (die) on the wafer. Unique nanoscale features were patterned in a 5 mm×5 mm square (device) and arrayed in a 4×5 matrix on a die. Thus each die had a single microscale pattern across the full area of the die, divided into 20 devices, 5 mm×5 mm in size, each having one of the 20 nanoscale patterns.

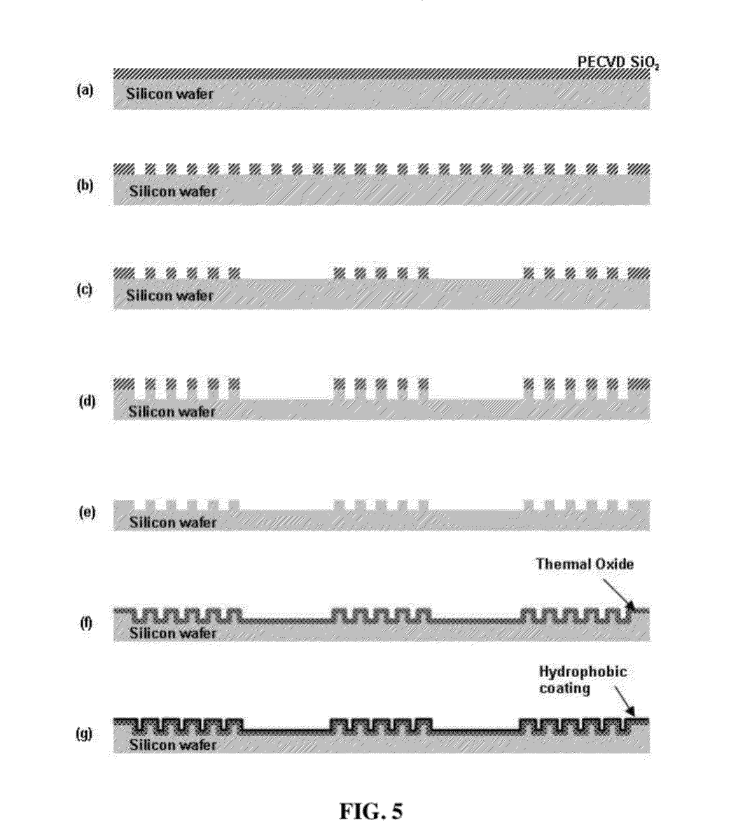

FIGS. 5A-5G illustrate the process flow for preparation of the individual and combined nanoscale and microscale features. FIG. 5A: 500 nm of PECVD silicon dioxide was deposited on 150 mm diameter silicon wafer. FIG. 5B: Nanoscale features were patterned and etched through the oxide. FIG. 5C: Microscale features were patterned and etched through the oxide. FIG. 5D: Using the patterned oxide as a hard mask, 2 μm-deep features were etched into silicon. FIG. 5E: The oxide hard mask was stripped using a dry etch process. FIG. 5F: After a piranha clean and deionized water (DI) rinse, a 50 nm-thick layer of thermal oxide was grown over the silicon. FIG. 5G: The structures were coated with a thin hydrophobic layer.

### Microscale Features

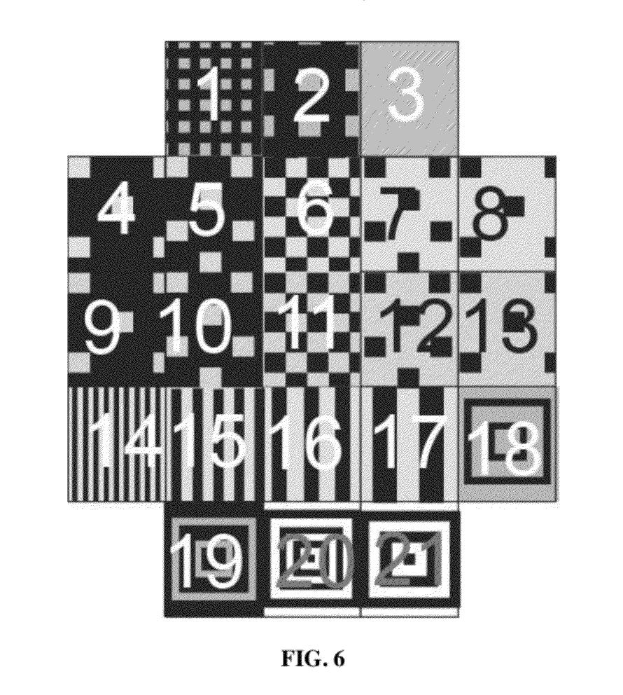

A microscale test mask was prepared containing 20 different regions of microscaled features regions, plus one featureless region (indicated by “none”). Table 1 shows the dimensions of the microscaled features where Die No. corresponds to the numbering in FIG. 6, Name is the designation for the microscaled feature, Width is the feature width in micrometers, Space is the distance between features in micrometers, and Pitch is the total distance of the Width and Space. A graphic representation of the test mask is seen in FIG. 6.

TABLE 1

| Die No. | Name | Width (μm) | Space (μm) | Pitch (μm) |
|---|---|---|---|---|
| 1 | Street-20/20 | 20 | 20 | 40 |
| 2 | Street-50/50 | 50 | 50 | 100 |
| 3 | None | 0 | 0 | 0 |
| 4 | Checkerboard 60/20 | 60 | 20 | 80 |
| 5 | Checkerboard 40/20 | 40 | 20 | 60 |
| 6 | Checkerboard 20/20 | 20 | 20 | 40 |
| 7 | Checkerboard 20/40 | 20 | 40 | 60 |
| 8 | Checkerboard 20/60 | 20 | 60 | 80 |
| 9 | Checkerboard 150/50 | 150 | 50 | 200 |
| 10 | Checkerboard 100/50 | 100 | 50 | 150 |
| 11 | Checkerboard 50/50 | 50 | 50 | 100 |
| 12 | Checkerboard 50/100 | 50 | 100 | 150 |
| 13 | Checkerboard 50/150 | 50 | 150 | 200 |
| 14 | Line 10/10 | 10 | 10 | 20 |
| 15 | Line 20/20 | 20 | 20 | 40 |
| 16 | Line 30/30 | 30 | 30 | 60 |
| 17 | Line 50/50 | 50 | 50 | 100 |
| 18 | Bull's-eye 20/50 | 20 | 50 | 70 |
| 19 | Bull's-eye 50/20 | 50 | 20 | 70 |
| 20 | Bull's-eye 20/20 | 20 | 20 | 40 |
| 21 | Bull's-eye 50/50 | 50 | 50 | 100 |

### Nanoscale Features

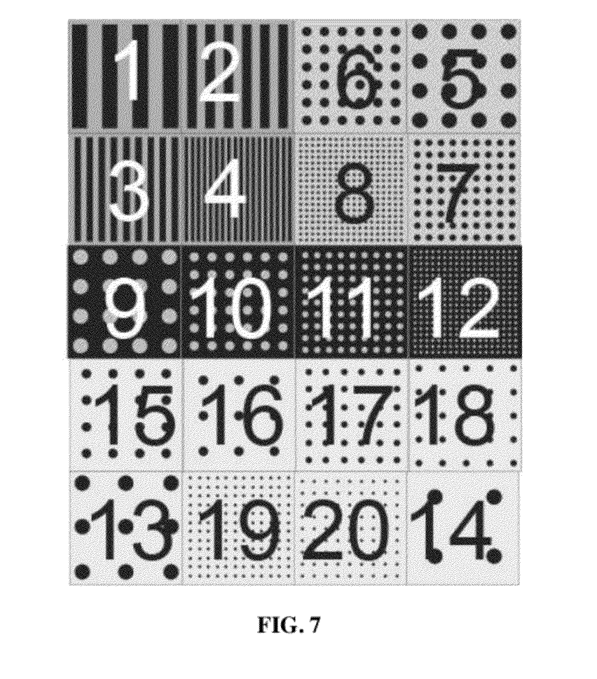

A nanoscale test mask was prepared containing 20 regions of nanoscale features. Table 2 shows the dimensions of the nanoscaled features where Device No. corresponds to the numbering in FIG. 7, Name is the designation for the nanoscaled feature, Width is the feature width in nanometers, Space is the distance between features in nanometers, and Pitch is the total distance of the Width and Space. A graphic representation of the test mask is seen in FIG. 7.

TABLE 2

| Device | | | | |
|---|---|---|---|---|
| No. | Name | Width (nm) | Space (nm) | Pitch (nm) |
| 1 | Dense Line-1000 | 1000 | 1000 | 2000 |
| 2 | Dense Line-600 | 600 | 600 | 1200 |
| 3 | Dense Line-400 | 400 | 400 | 800 |
| 4 | Dense Line-200 | 200 | 200 | 400 |
| 5 | Dense Post-1000 | 1000 | 1000 | 2000 |
| 6 | Dense Post-600 | 600 | 600 | 1200 |
| 7 | Dense Post-400 | 400 | 400 | 800 |
| 8 | Dense Post-200 | 200 | 200 | 400 |
| 9 | Dense Hole-1000 | 1000 | 1000 | 2000 |
| 10 | Dense Hole-600 | 600 | 600 | 1200 |
| 11 | Dense Hole-400 | 400 | 400 | 800 |
| 12 | Dense Hole-200 | 200 | 200 | 400 |
| 13 | Isolated Post- | 1000 | 2000 | 3000 |
| | 1000/2000 | | | |
| 14 | Isolated Post- | 1000 | 3000 | 4000 |
| | 1000/3000 | | | |
| 15 | Isolated Post- | 600 | 1200 | 1800 |
| | 600/1200 | | | |
| 16 | Isolated Post- | 600 | 1800 | 2400 |
| | 600/1800 | | | |
| 17 | Isolated Post-400/800 | 400 | 800 | 1200 |
| 18 | Isolated Post-400- | 400 | 1200 | 1600 |
| | 1200 | | | |
| 19 | Isolated Post-200/400 | 200 | 400 | 600 |
| 20 | Isolated Post-200/600 | 200 | 600 | 800 |

### Surface Modification

To enhance the hydrophobicity of the structured surface, individual dies were coated with a hydrophobic film (see FIG. 5G). Three different organic hydrophobic films were investigated, polydimethylsiloxane (PDMS) and two fluoropolymers: CYTOP grade 809M (Asahi Glass Co.) and Teflon AF1601 (Du Pont). A surface grafting process which created a covalently attached polymer was used to produce a conformal coating for each film.

For surface grafting of PDMS, 1000 cSt PDMS was spin-coated at 1000 rpm for 1 min. After spinning, the material was soft baked at 120° C. for 5 min and then hard baked at 220° C. on a hot plate for 1 hr. After baking, the non-grafted PDMS was stripped by submerging the die in a bath of hexane. The resulting conformal layer was measured by ellipsometry to be less than 10 nm thick. The contact angle of a deionized water drop on a planar surface of this film was measured at 105°.

For surface grafting of CYTOP, 9% CYTOP was spin-coated at 550 rpm for 1 min. After spinning, the material was soft baked at 120° C. for 5 min and then hard baked at 220° C. on a hot plate for 1 hr. After baking, the non-grafted CYTOP was stripped by submerging the die in a bath of FC-40 (3M). The resulting conformal layer was measured to be less than 15 nm thick. The contact angle of a deionized water drop on a planar surface of this film measured at 116°.

For surface grafting of Teflon AF, Teflon AF1601 was spin-coated at 550 rpm for 1 min. After spinning, the material was soft baked at 120° C. for 5 min and then hard baked at 220° C. on a hot plate for 1 hr. After baking, the non-grafted Teflon AF was stripped by submerging the die in a bath of FC-40 (3M). The resulting conformal layer was measured to be less than 15 nm thick. The contact angle of a deionized water drop on a planar surface of this film measured at 122°.

### Contact Angle Measurement

Equilibrium contact angle data was collected for each microscale pattern, each nanoscale pattern, and each dual-scale pattern, for each hydrophobic film type. A 10 μL sessile drop of water was placed at the center of a 5 mm×5 mm device on the die and contact angle data at the three phase contact line was obtained using a Ramé-Hart model 200 goniometer. Because of the asymmetry of the line patterns, two contact angle values were recorded for these. One contact angle was recorded while viewing the drop perpendicular to the direction of the lines, and a contact angle while viewing the drop parallel with the lines.

### Slide Angle Measurement

The slide angle was measured by first securing a die on a 75 mm×50 mm aluminum plate. Next a 10 μL sessile drop of DI water was dispensed on the center of a 5 mm×5 mm nano-scale device or at the center of the die for a micro-scale-only feature. The plate containing the die and drop was tilted with a linear actuator (Newport 850b, 25 mm stroke, 0-1 mm/s) by pushing vertically upward on the bottom of the plate at one end while keeping the other end hinged. The height at which the drop began to roll was recorded. Since the horizontal distance between the hinge point and linear actuator was constant, the slide angle could be determined once the stroke height was measured. The angle measurement was repeated a minimum of three times for each feature tested. The stroke limit of the actuator and practical constraints on its placement relative to the hinge point only allowed a maximum tilt of 45°. Once a test reached the stroke limit, the plate was manually rotated through 90°. If the drop stayed on the surface at 90° it was classified as being pinned, if it rolled prior to 90° but was greater than 45° it was classified as >45°. Less than 45° the actual angle was recorded. Two different slide angle measurements were made for the nano-scale and micro-scale line structures, one with the drop rolling parallel with the lines and one with the drop rolling perpendicular to the lines.

### Electrowetting Measurement

The electrowetting experimental setup is illustrated in FIG. 3. The silicon substrate used for each structure served as the ground electrode and was held at 0 V during the testing. An AC or DC potential was applied to a 0.5 mm diameter platinum wire electrode (CH Instruments model CHI115) which was brought into contact with a 10 μL sessile drop of water resting atop the center of a 5 mm×5 mm device on the die. Starting at 0 V, contact angle was measured while a constant potential was applied (on-state). After the on-state measurement was made, the potential was returned to zero, and the contact angle was measured again (off-state). This process was repeated as the potential was increased incrementally. Once no further contact angle change was observed from incremental increases in potential, the test was stopped. Three different aqueous water phases were tested: 1 mM NaCl, 10 mM NaCl, and 100 mM NaCl. All experiments were conducted in ambient air. The CYTOP and Teflon coated structures were tested in DC only and the PDMS coated samples tested in AC only. AC potential was applied as a square wave at 500 Hz.

### Water Contact Angle on Microscale-Only Patterns

The contact angle of water on patterns of microscale-only features coated with PDMS, CYTOP, or Teflon AF was measured and compared to a featureless surface coated with PDMS, CYTOP, or Teflon AF. The results show that for PDMS, the presence of microscale features led to an increase in water contact angle. Many of the microscale feature patterns showed increases in water contact angles of greater then 20° to a maximum of 44° relative to a featureless surface. The results also showed that for CYTOP, many microscale feature patterns led to an increase in water contact angle of greater than 15° to a maximum of 23° relative to a featureless surface. For Teflon AF, many microscale feature patterns led to an increase in water contact angle of greater then 15° to a maximum of 31° relative to a featureless surface. These results showed that a pattern of microscale-only features increased the water contact angle over that of a featureless surface of the same organic coating. Table 3 provides a summary of water contact angles on patterns of microscale-only features having different organic coatings. Contact angle is given in degrees (°). The contact angles for line features are asymmetric and the largest values are given.

TABLE 3

| Die No. | Name | PDMS | CYTOP | Teflon AF |
|---|---|---|---|---|
| 1 | Street-20/20 | 125 | 125 | 128 |
| 2 | Street-50/50 | 107 | 119 | 127 |
| 3 | None | 105 | 116 | 123 |
| 4 | Checkerboard 60/20 | 112 | 119 | 126 |
| 5 | Checkerboard 40/20 | 115 | 125 | 129 |
| 6 | Checkerboard 20/20 | 128 | 121 | 141 |
| 7 | Checkerboard 20/40 | 116 | 121 | 127 |
| 8 | Checkerboard 20/60 | 106 | 120 | 126 |
| 9 | Checkerboard 150/50 | 109 | 137 | 128 |
| 10 | Checkerboard 100/50 | 114 | 125 | 129 |
| 11 | Checkerboard 50/50 | 132 | 139 | 142 |
| 12 | Checkerboard 50/100 | 105 | 119 | 126 |
| 13 | Checkerboard 50/150 | 105 | 117 | 125 |
| 14 | Line 10/10 | 125 | 135 | 140 |
| 15 | Line 20/20 | 127 | 133 | 138 |
| 16 | Line 30/30 | 121 | 136 | 136 |
| 17 | Line 50/50 | 120 | 134 | 136 |
| 18 | Bull's-eye 20/50 | 149 | 139 | 154 |
| 19 | Bull's-eye 50/20 | 146 | 127 | 149 |
| 20 | Bull's-eye 20/20 | 146 | 135 | 152 |
| 21 | Bull's-eye 50/50 | 142 | 127 | 151 |

### Water Contact Angle on Nanoscale-Only Patterns

The contact angle of water on patterns of nanoscale-only features coated with either PDMS, CYTOP, or Teflon AF was measured and compared with a featureless surface coated with PDMS, CYTOP, or Teflon AF. The results showed that for PDMS, many patterns of nanoscale features led to an increase in water contact angle of greater then 20° to a maximum of 50° relative to a featureless surface. The results also showed that for CYTOP, many patterns of nanoscale features led to an increase in water contact angle of greater then 20° to a maximum of 41° relative to a featureless surface. For Teflon AF, many patterns of nanoscale features led to an increase in water contact angle of greater then 20° to a maximum of 38° relative to a featureless surface. These results showed that patterns of nanoscale features increased the water contact angle over that of a featureless surface of the same organic coating. Table 4 presents a summary of water contact angles of patterns of nanoscale features having different organic coatings. Contact angle is given in degrees (°). The contact angles for line features are asymmetric and the largest values are given.

TABLE 4

| Device No. | Name | PDMS | CYTOP | Teflon AF |
|---|---|---|---|---|
| 1 | Dense Line-1000 | 108 | 137 | 136 |
| 2 | Dense Line-600 | 113 | 123 | 145 |
| 3 | Dense Line-400 | 113 | 126 | 140 |
| 5 | Dense Post-1000 | 120 | 153 | 154 |
| 6 | Dense Post-600 | 123 | 138 | 160 |
| 7 | Dense Post-400 | 124 | 154 | 155 |
| 9 | Dense Hole-1000 | 118 | 119 | 122 |
| 10 | Dense Hole-600 | 117 | 123 | 130 |
| 11 | Dense Hole-400 | 117 | 120 | 128 |
| 13 | Isolated Post- | 147 | 156 | 150 |
| | 1000/2000 | | | |
| 14 | Isolated Post- | 131 | 129 | 159 |
| | 1000/3000 | | | |
| 15 | Isolated Post- | 155 | 157 | 151 |
| | 600/1200 | | | |
| 16 | Isolated Post- | 135 | 135 | 161 |
| | 600/1800 | | | |

Water Contact Angle on Dual-scale Patterns with Microscale Street-20/20 and Street-50/50

The contact angle of water on patterns of dual-scale features coated with either PDMS, CYTOP, or Teflon AF was measured. The microscale patterns tested were Street-20/20 and Street-50/50; each nanoscale pattern was tested on each of these. The results showed that for all three organic coatings, the dual-scale patterns had a contact angle greater than that of only microscale-only surfaces. For some nanoscale-only patterns, the dual-scale patterns had an equal or greater contact angle, but for other nanoscale-only patterns, the dual-scale contact angles were less. These results showed that some combined dual-scale patterns increased the water contact angle over that of either nanoscale-only or microscale-only features. Table 5 presents a summary of water contact angles of nanoscale features on Street microscale features with different organic coatings. Contact angle is given in degrees (°). The contact angles for line features are asymmetric and the largest values are given.

TABLE 5

| | Street 20/20 | | | Street 50/50 | | |
|---|---|---|---|---|---|---|
| | | | Teflon | | | Teflon |
| Name | PDMS | CYTOP | AF | PDMS | CYTOP | AF |
| Dense | 126 | 124 | 129 | 111 | 119 | 125 |
| Line-1000 | | | | | | |
| Dense | 123 | 124 | 131 | 144 | 121 | 131 |
| Line-600 | | | | | | |
| Dense | 149 | 124 | 131 | 108 | 127 | 124 |
| Line-400 | | | | | | |
| Dense | 121 | 126 | 132 | 119 | 116 | 128 |
| Post-1000 | | | | | | |
| Dense Post-600 | 130 | 130 | 136 | 115 | 132 | 137 |
| Dense Post-400 | 122 | 129 | 134 | 121 | 125 | 127 |
| Dense | 119 | 125 | 131 | 110 | 123 | 123 |
| Hole-1000 | | | | | | |
| Dense | 121 | 124 | 130 | 115 | 123 | 128 |
| Hole-600 | | | | | | |
| Dense | 121 | 126 | 132 | 116 | 122 | 130 |
| Hole-400 | | | | | | |
| Isolated Post- | 107 | 126 | 134 | 111 | 125 | 129 |
| 1000/2000 | | | | | | |
| Isolated Post- | 106 | 120 | 123 | 112 | 116 | 121 |
| 1000/3000 | | | | | | |
| Isolated Post- | 121 | 128 | 134 | 115 | 128 | 129 |
| 600/1200 | | | | | | |
| Isolated Post- | 110 | 120 | 123 | 112 | 119 | 128 |
| 600/1800 | | | | | | |

Water Contact Angle of PDMS-Coated Dual-Scale Patterns with Checkerboard Microscale Features

The contact angle of water on combined patterns of dual-scale features coated with PDMS was measured. These results showed that the Checkerboard 60/20, 40/20, and 20/20 microscale features combined with nanoscale features increased contact angle relative to either the nanoscale-only pattern or microscale-only pattern. The dual-scale checkerboard 60/20, 40/20, or 20/20 with either dense line or dense post nanoscale features had the largest increase in contact angle with increases ranging from 20° to 40°. Table 6 presents a summary of water contact angles of patterns of dual-scale features having PDMS coatings. Contact angle is given in degrees (°). The contact angles for line features are asymmetric and the largest values are given.

TABLE 6

| | Checkerboard | | | | |
|---|---|---|---|---|---|
| Name | 60/20 | 40/20 | 20/20 | 20/40 | 20/60 |
| Dense Line-1000 | 116 | 135 | 145 | 113 | 111 |
| Dense Line-600 | 116 | 136 | 151 | 112 | 110 |
| Dense Line-400 | 117 | 135 | 145 | 113 | 110 |
| Dense Post-1000 | 149 | 146 | 153 | 116 | 107 |
| Dense Post-600 | 151 | 151 | 153 | 117 | 104 |
| Dense Post-400 | 153 | 148 | 157 | 118 | 103 |
| Dense Hole-1000 | 119 | 122 | 127 | 115 | 101 |
| Dense Hole-600 | 119 | 118 | 125 | 115 | 113 |
| Dense Hole-400 | 117 | 110 | 131 | 113 | 111 |
| Isolated Post- | 158 | 132 | 120 | 114 | 107 |
| 1000/2000 | | | | | |
| Isolated Post- | 124 | 122 | 116 | 112 | 110 |
| 1000/3000 | | | | | |
| Isolated Post-600/1200 | 156 | 146 | 125 | 114 | 107 |
| Isolated Post-600/1800 | 133 | 127 | 117 | 111 | 107 |

Water Contact Angle of CYTOP-Coated Dual-Scale Patterns with Checkerboard Microscale Features

The contact angle of water on patterns of dual-scale features coated with CYTOP was measured. These results showed that the checkerboard 60/20, 40/20, and 20/20 microscale features combined with nanoscale features increased contact angle relative to nanoscale-only features or microscale-only features. The combination of checkerboard 60/20, 40/20, or 20/20 with dense line or dense post nanoscale features had the largest increase in contact angle, with increases ranging from 10° to 30°. Table 7 presents a summary of water contact angles of patterns of dual-scale features having CYTOP coatings. Contact angle is given in degrees (°). The contact angles for line features are asymmetric and the largest values are given.

TABLE 7

| | Checkerboard | | | | |
|---|---|---|---|---|---|
| Name | 60/20 | 40/20 | 20/20 | 20/40 | 20/60 |
| Dense Line-1000 | 140 | 142 | 141 | 124 | 118 |
| Dense Line-600 | 142 | 145 | 144 | 124 | 120 |
| Dense Line-400 | 134 | 146 | 144 | 126 | 120 |
| Dense Post-1000 | 159 | 155 | 153 | 125 | 119 |
| Dense Post-600 | 158 | 160 | 159 | 127 | 122 |
| Dense Post-400 | 163 | 159 | 159 | 124 | 120 |
| Dense Hole-1000 | 121 | 127 | 125 | 122 | 119 |
| Dense Hole-600 | 124 | 128 | 124 | 122 | 121 |
| Dense Hole-400 | 124 | 128 | 122 | 122 | 121 |
| Isolated Post- | 158 | 159 | 157 | 119 | 119 |
| 1000/2000 | | | | | |
| Isolated Post- | 129 | 128 | 132 | 116 | 117 |
| 1000/3000 | | | | | |
| Isolated Post-600/1200 | 159 | 159 | 158 | 125 | 119 |
| Isolated Post-600/1800 | 160 | 135 | 167 | 118 | 118 |

Water Contact Angle of Teflon AF-Coated Dual-Scale Patterns with Checkerboard Microscale Features

The contact angle of water on patterns of dual-scale features coated with Teflon AF was measured. These results showed that the checkerboard microscale features combined with the nanoscale features had similar contact angles to the nanoscale-only features, and greater contact angles then the microscale-only features. The combination of checkerboard 60/20, 40/20, or 20/20 with either dense line or dense post nanoscale features had the largest increase in contact angle with increases up to 10°. Table 8 presents a summary of water contact angles of dual-scale features having Teflon AF coatings. Contact angle is given in degrees (°). The contact angles for line features are asymmetric and the largest values are given.

TABLE 8

| | Checkerboard | | | | |
|---|---|---|---|---|---|
| Name | 60/20 | 40/20 | 20/20 | 20/40 | 20/60 |
| Dense Line-1000 | 143 | 142 | 143 | 131 | 126 |
| Dense Line-600 | 147 | 148 | 147 | 132 | 128 |
| Dense Line-400 | 148 | 147 | 149 | 132 | 126 |
| Dense Post-1000 | 149 | 157 | 159 | 130 | 127 |
| Dense Post-600 | 160 | 160 | 154 | 132 | 127 |
| Dense Post-400 | 154 | 157 | 165 | 132 | 127 |
| Dense Hole-1000 | 129 | 129 | 127 | 128 | 125 |
| Dense Hole-600 | 134 | 133 | 131 | 125 | 124 |
| Dense Hole-400 | 130 | 133 | 128 | 127 | 126 |
| Isolated Post- | 156 | 157 | 155 | 129 | 125 |
| 1000/2000 | | | | | |
| Isolated Post- | 137 | 135 | 146 | 122 | 123 |
| 1000/3000 | | | | | |
| Isolated Post-600/1200 | 158 | 157 | 154 | 132 | 125 |
| Isolated Post-600/1800 | 161 | 165 | 160 | 122 | 124 |

Water Contact Angle of PDMS-Coated Dual-scale Patterns with Checkerboard Microscale Features

The contact angle of water on patterns of dual-scale features coated with PDMS was measured. These results showed that the checkerboard 150/50, 100/50, and 50/50 microscale features combined with the nanoscale features had increased contact angle relative to either the nanoscale-only features or microscale-only features. The combination of checkerboard 150/50, 100/50, or 50/50 with either dense line or dense post nanoscale features had the largest increase in contact angle with increases ranging from 20° to 40°. Table 9 presents a summary of water contact angles of dual-scale features having PDMS coatings. Contact angle is given in degrees (°). The contact angles for line features are asymmetric and the largest values are given.

TABLE 9

| | Checkerboard | | | | |
|---|---|---|---|---|---|
| Name | 150/50 | 100/50 | 50/50 | 50/100 | 50/150 |
| Dense Line-1000 | 130 | 136 | 146 | 112 | 107 |
| Dense Line-600 | 136 | 137 | 147 | 113 | 109 |
| Dense Line-400 | 113 | 137 | 145 | 111 | 106 |
| Dense Post-1000 | 151 | 151 | 147 | 113 | 112 |
| Dense Post-600 | 151 | 153 | 155 | 116 | 111 |
| Dense Post-400 | 154 | 153 | 150 | 113 | 111 |
| Dense Hole-1000 | 116 | 123 | 131 | 108 | 108 |
| Dense Hole-600 | 116 | 120 | 135 | 110 | 113 |
| Dense Hole-400 | 117 | 121 | 134 | 112 | 111 |
| Isolated Post- | 152 | 143 | 122 | 113 | 107 |
| 1000/2000 | | | | | |
| Isolated Post- | 125 | 123 | 113 | 106 | 108 |
| 1000/3000 | | | | | |
| Isolated Post-600/1200 | 152 | 157 | 136 | 113 | 106 |
| Isolated Post-600/1800 | 135 | 120 | 115 | 110 | 110 |

Water Contact Angle of CYTOP-coated Dual-scale Patterns with Checkerboard Microscale Features

The contact angle of water on patterns of dual-scale features coated with CYTOP was measured. These results showed that the checkerboard 150/50, 100/50, and 50/50 microscale features combined with the nanoscale features had increased contact angles relative to either the nanoscale-only features or microscale-only features. The combination of checkerboard 150/50, 100/50, or 50/50 with dense line, dense post, or dense holes nanoscale features had the largest increase in contact angle with increases ranging from 15° to 40°. Table 10 presents a summary of water contact angles of dual-scale features having CYTOP coatings. Contact angle is given in degrees (°). The contact angles for line features are asymmetric and the largest values are given.

TABLE 10

| | Checkerboard | | | | |
|---|---|---|---|---|---|
| Name | 150/50 | 100/50 | 50/50 | 50/100 | 50/150 |
| Dense Line-1000 | 152 | 140 | 150 | 120 | 118 |
| Dense Line-600 | 155 | 146 | 156 | 121 | 120 |
| Dense Line-400 | 154 | 144 | 154 | 120 | 118 |
| Dense Post-1000 | 154 | 155 | 158 | 125 | 117 |
| Dense Post-600 | 160 | 160 | 160 | 124 | 123 |
| Dense Post-400 | 159 | 161 | 157 | 124 | 120 |
| Dense Hole-1000 | 134 | 122 | 133 | 119 | 118 |
| Dense Hole-600 | 138 | 128 | 139 | 120 | 118 |
| Dense Hole-400 | 137 | 127 | 137 | 121 | 119 |
| Isolated Post- | 120 | 158 | 132 | 118 | 118 |
| 1000/2000 | | | | | |
| Isolated Post- | 118 | 125 | 115 | 115 | 114 |
| 1000/3000 | | | | | |
| Isolated Post-600/1200 | 148 | 157 | 158 | 122 | 120 |
| Isolated Post-600/1800 | 118 | 135 | 122 | 118 | 118 |

Water Contact Angle of Teflon AF-Coated Dual-Scale Patterns with Checkerboard Microscale Features

The contact angle of water on patterns of dual-scale features coated with Teflon AF was measured. These results showed that the checkerboard 150/50, 100/50, and 50/50 microscale features combined with the nanoscale features had increased contact angles relative to either the nanoscale-only features or microscale-only features. The combination of checkerboard 150/50, 100/50, or 50/50 with dense line, dense post, or dense holes nanoscale features had the largest increase in contact angle with increases ranging from 10° to 20°. Table 11 presents a summary of water contact angles of dual-scale features having Teflon AF coatings. Contact angle is given in degrees (°). The contact angles for line features are asymmetric and the largest values are given.

TABLE 11

| | Checkerboard | | | | |
|---|---|---|---|---|---|
| Name | 150/50 | 100/50 | 50/50 | 50/100 | 50/150 |
| Dense Line-1000 | 150 | 144 | 149 | 124 | 125 |
| Dense Line-600 | 157 | 150 | 155 | 128 | 124 |
| Dense Line-400 | 152 | 147 | 151 | 128 | 127 |
| Dense Post-1000 | 161 | 157 | 158 | 128 | 128 |
| Dense Post-600 | 160 | 160 | 160 | 129 | 125 |
| Dense Post-400 | 163 | 161 | 164 | 129 | 129 |
| Dense Hole-1000 | 137 | 130 | 138 | 127 | 126 |
| Dense Hole-600 | 144 | 132 | 140 | 127 | 126 |
| Dense Hole-400 | 142 | 132 | 141 | 124 | 125 |
| Isolated Post- | 155 | 157 | 159 | 125 | 126 |
| 1000/2000 | | | | | |
| Isolated Post- | 126 | 130 | 129 | 125 | 123 |
| 1000/3000 | | | | | |
| Isolated Post-600/1200 | 154 | 157 | 161 | 125 | 128 |
| Isolated Post-600/1800 | 131 | 160 | 133 | 124 | 123 |

Water Contact Angle of PDMS-Coated Dual-Scale Patterns with Line Microscale Features

The contact angle of water on patterns of dual-scale features coated with PDMS was measured. These results showed that the line microscale features combined with the nanoscale features had increased contact angles relative to the nanoscale-only features for the dense lines, dense posts, and dense holes, but not other nanoscale-only features. The line microscale features combined with the nanoscale features had increased contact angles relative to the microscale-only features for all dual-scale features with increases ranging from 10° to 40°. Table 12 presents a summary of water contact angles of combined nano- and micro-scale features having PDMS coatings. Contact angle is given in degrees (°). The contact angles for line features are asymmetric and the largest values are given.

TABLE 12

Lines

| Name | 10/10 | 20/20 | 30/30 | 50/50 |
|---|---|---|---|---|
| Dense Line-1000 | 132 | 123 | 124 | 120 |
| Dense Line-600 | 144 | 127 | 123 | 123 |
| Dense Line-400 | 133 | 126 | 129 | 136 |
| Dense Post-1000 | 134 | 134 | 131 | 130 |
| Dense Post-600 | 158 | 127 | 131 | 126 |
| Dense Post-400 | 150 | 155 | 151 | 139 |
| Dense Hole-1000 | 128 | 123 | 120 | 121 |
| Dense Hole-600 | 130 | 123 | 121 | 122 |
| Dense Hole-400 | 128 | 125 | 122 | 122 |
| Isolated Post- | 149 | 119 | 116 | 116 |
| 1000/2000 | | | | |
| Isolated Post- | 116 | 111 | 112 | 113 |
| 1000/3000 | | | | |
| Isolated Post-600/1200 | 148 | 129 | 125 | 126 |
| Isolated Post-600/1800 | 114 | 114 | 110 | 113 |

Water Contact Angle of CYTOP-Coated Dual-Scale Patterns with Line Microscale Features

The contact angle of water on patterns of dual-scale features coated with CYTOP was measured. These results showed that the line microscale features combined with the nanoscale features had increased contact angles relative to the nanoscale-only features for the dense lines, dense posts, and dense holes, but not other nanoscale-only features. The line microscale features combined with the nanoscale features had increased contact angles relative to the microscale-only features for all dual-scale features with increases ranging from 10° to 30°. Table 13 presents a summary of water contact angles of dual-scale features having CYTOP coatings. Contact angle is given in degrees (°). The contact angles for line features are asymmetric and the largest values are given.

TABLE 13

Lines

| Name | 10/10 | 20/20 | 30/30 | 50/50 |
|---|---|---|---|---|
| Dense Line-1000 | 142 | 147 | 146 | 148 |
| Dense Line-600 | 149 | 151 | 148 | 147 |
| Dense Line-400 | 136 | 151 | 133 | 130 |
| Dense Post-1000 | 159 | 158 | 138 | 138 |
| Dense Post-600 | 162 | 163 | 138 | 153 |
| Dense Post-400 | 162 | 135 | 134 | 153 |
| Dense Hole-1000 | 133 | 136 | 135 | 136 |
| Dense Hole-600 | 137 | 136 | 136 | 133 |
| Dense Hole-400 | 136 | 135 | 134 | 137 |
| Isolated Post- | 138 | 141 | 146 | 143 |
| 1000/2000 | | | | |
| Isolated Post- | 119 | 119 | 118 | 119 |
| 1000/3000 | | | | |
| Isolated Post-600/1200 | 154 | 151 | 146 | 139 |
| Isolated Post-600/1800 | 124 | 117 | 117 | 116 |

Water Contact Angle of Teflon AF-Coated Dual-Scale Patterns with Line Microscale Features

The contact angle of water on patterns of dual-scale features coated with Teflon AF was measured. These results showed that the line microscale features combined with the nanoscale features had increased contact angles relative to the nanoscale-only features for the dense lines, dense posts, and dense holes, but not other nanoscale-only features. The line microscale features combined with the nanoscale features had increased contact angles relative to the microscale-only features for all dual-scale features with increases ranging from 10° to 20°. Table 14 presents a summary of water contact angles of dual-scale features having CYTOP coatings. Contact angle is given in degrees (°). The contact angles for line features are asymmetric and the largest values are given.

TABLE 14

Lines

| Name | 10/10 | 20/20 | 30/30 | 50/50 |
|---|---|---|---|---|
| Dense Line-1000 | 150 | 150 | 148 | 139 |
| Dense Line-600 | 153 | 151 | 150 | 153 |
| Dense Line-400 | 155 | 141 | 155 | 145 |
| Dense Post-1000 | 163 | 161 | 157 | 156 |
| Dense Post-600 | 162 | 162 | 158 | 165 |
| Dense Post-400 | 167 | 149 | 141 | 142 |
| Dense Hole-1000 | 141 | 140 | 138 | 136 |
| Dense Hole-600 | 141 | 137 | 140 | 140 |
| Dense Hole-400 | 139 | 137 | 136 | 139 |
| Isolated Post- | 158 | 163 | 153 | 147 |
| 1000/2000 | | | | |
| Isolated Post- | 140 | 126 | 123 | 126 |
| 1000/3000 | | | | |
| Isolated Post-600/1200 | 160 | 164 | 142 | 150 |
| Isolated Post-600/1800 | 153 | 153 | 126 | 146 |

Water Contact Angle of PDMS-Coated Dual-Scale Patterns with Bull's-Eye Microscale Features

The contact angle of water on patterns of dual-scale features coated with PDMS was measured. These results show that the bull's-eye microscale features combined with the nanoscale features had increased contact angles relative to the nanoscale-only features for the dense lines, dense posts, and dense holes, but not other nanoscale-only features. The bull's-eye microscale features combined with the nanoscale features had increased contact angles relative to the microscale-only features for all dual-scale features with increases ranging from 20° to 40°. Table 15 presents a summary of water contact angles of dual-scale features having PDMS coatings. Contact angle is given in degrees (°). The contact angles for line features are asymmetric and the largest values are given.

TABLE 15

Bull's-eye

| Name | 20/50 | 50/20 | 20/20 | 50/50 |
|---|---|---|---|---|
| Dense Line-1000 | 144 | 142 | 143 | 148 |
| Dense Line-600 | 149 | 147 | 148 | 143 |
| Dense Line-400 | 148 | 135 | 141 | 140 |
| Dense Post-1000 | 147 | 146 | 147 | 156 |
| Dense Post-600 | 154 | 150 | 156 | 153 |
| Dense Post-400 | 148 | 145 | 155 | 149 |
| Dense Hole-1000 | 140 | 144 | 140 | 145 |
| Dense Hole-600 | 142 | 147 | 145 | 146 |
| Dense Hole-400 | 143 | 144 | 144 | 148 |
| Isolated Post- | 140 | 141 | 146 | 133 |
| 1000/2000 | | | | |
| Isolated Post- | 119 | 117 | 126 | 134 |
| 1000/3000 | | | | |
| Isolated Post-600/1200 | 143 | 155 | 150 | 128 |
| Isolated Post-600/1800 | 136 | 142 | 141 | 138 |

Water Contact Angle of CYTOP-Coated Dual-Scale Patterns with Bull's-Eye Microscale Features

The contact angle of water on patterns of dual-scale features coated with CYTOP was measured. These results showed that the bull's-eye microscale features combined with the nanoscale features had increased contact angles relative to the nanoscale features for the dense lines, dense posts, and dense holes, but not other nanoscale-only features. The bull's-eye microscale features combined with the nanoscale features had increased contact angles relative to the microscale-only features for all dual-scale features with increases ranging from 10° to 40°. Table 16 presents a summary of water contact angles of dual-scale features having CYTOP coatings. Contact angle is given in degrees (°). The contact angles for line features are asymmetric and the largest values are given.

TABLE 16

Bull's-eye

| Name | 20/50 | 50/20 | 20/20 | 50/50 |
|---|---|---|---|---|
| Dense Line-1000 | 154 | 147 | 146 | 148 |
| Dense Line-600 | 155 | 156 | 157 | 153 |
| Dense Line-400 | 154 | 139 | 152 | 150 |
| Dense Post-1000 | 156 | 152 | 154 | 158 |
| Dense Post-600 | 151 | 159 | 159 | 159 |
| Dense Post-400 | 157 | 153 | 155 | 160 |
| Dense Hole-1000 | 149 | 149 | 145 | 144 |
| Dense Hole-600 | 155 | 147 | 150 | 149 |
| Dense Hole-400 | 154 | 149 | 150 | 143 |
| Isolated Post- | 157 | 156 | 155 | 150 |
| 1000/2000 | | | | |
| Isolated Post- | 135 | 134 | 131 | 127 |
| 1000/3000 | | | | |
| Isolated Post-600/1200 | 141 | 158 | 154 | 152 |
| Isolated Post-600/1800 | 139 | 163 | 151 | 149 |

Water Contact Angle of Teflon AF-Coated Dual-Scale Patterns with Bull's-Eye Microscale Features

The contact angle of water on patterns of dual-scale features coated with Teflon AF was measured. These results showed that the bull's-eye microscale features combined with the nanoscale features have increased contact angles relative to the nanoscale-only features for the dense lines and dense holes, but not other nanoscale-only features. The bull's-eye microscale features combined with the nanoscale features had increased contact angles relative to the microscale-only features for all dual-scale features with increases ranging from 10° to 40°. Table 17 presents a summary of water contact angles of dual-scale features having Teflon AF coatings. Contact angle is given in degrees (°). The contact angles for line features are asymmetric and the largest values are given.

TABLE 17

Bull's-eye

| Name | 20/50 | 50/20 | 20/20 | 50/50 |
|---|---|---|---|---|
| Dense Line-1000 | 157 | 151 | 145 | 150 |
| Dense Line-600 | 159 | 157 | 158 | 159 |
| Dense Line-400 | 156 | 152 | 148 | 154 |
| Dense Post-1000 | 158 | 154 | 160 | 148 |
| Dense Post-600 | 138 | 163 | 161 | 162 |
| Dense Post-400 | 160 | 156 | 158 | 159 |
| Dense Hole-1000 | 155 | 139 | 143 | 147 |
| Dense Hole-600 | 152 | 150 | 151 | 151 |
| Dense Hole-400 | 156 | 150 | 153 | 150 |
| Isolated Post- | 159 | 157 | 150 | 156 |
| 1000/2000 | | | | |
| Isolated Post- | 160 | 156 | 159 | 156 |
| 1000/3000 | | | | |
| Isolated Post-600/1200 | 158 | 156 | 146 | 158 |
| Isolated Post-600/1800 | 163 | 163 | 162 | 161 |

### Recovery Angle of Water on Coated Microscale Features

The recovery angle of water on microscale features coated with PDMS, CYTOP, or Teflon AF was measured and compared to a featureless surface coated with PDMS, CYTOP, or Teflon AF. The recovery angle of water is a measure of the ability of the surface to switch its hydrophobicity in response to electrical stimulation. Specifically, the recovery angle is the difference in the water contact angle of the surface in its most hydrophilic state (on-state), which for this experiment was at an electrowetting voltage condition of 20 volts, and in its reversible hydrophobic state (off-state). The larger the recovery angle, the greater the ability of the surface to switch its level of hydrophobicity. A recovery angle of 0° is given when the surface remains in its more hydrophilic state after power is turned off.

The results showed that for CYTOP and Teflon AF, the recovery angle of water was either only marginally higher relative to a featureless surface, or in some cases lower than the featureless surface. PDMS-coated surfaces were not measured. These results also showed that microscale-only features offer little increase in the recovery angle of water over a featureless surface. Table 18 presents a summary of recovery angles for patterns of microscale features with different organic coatings. Recovery angle is given in degrees (°).

TABLE 18

| Name | CYTOP | Teflon AF |
|---|---|---|
| Street-20/20 | 20 | 24 |
| Street-50/50 | 37 | 15 |
| None | 33 | 15 |
| Checkerboard 60/20 | 29 | 28 |
| Checkerboard 40/20 | 23 | 0 |
| Checkerboard 20/20 | 0 | 0 |
| Checkerboard 20/40 | 29 | 21 |
| Checkerboard 20/60 | 38 | 12 |
| Checkerboard 150/50 | 16 | 12 |
| Checkerboard 100/50 | 19 | 22 |
| Checkerboard 50/50 | 0 | 10 |
| Checkerboard 50/100 | 36 | 11 |
| Checkerboard 50/150 | 33 | 11 |
| Line 10/10 | 41 | 22 |
| Line 20/20 | 39 | 22 |
| Line 30/30 | 38 | 16 |
| Line 50/50 | 37 | 19 |

Recovery Angle of Water on PDMS-Coated Dual-Scale Patterns with Dense-Line Nanoscale Features and Various Microscale Features

The recovery angle of water on patterns of dual-scale features coated with PDMS was measured and compared to a surface coated with PDMS containing only nanoscale features.

The results showed that for PDMS, the recovery angle of water in some cases was only marginally higher relative to a surface with nanoscale-only, or in other cases lower than the nanoscale-only surface. The results also showed that combinations of either checkerboard or line microscale features with dense line nanoscale features gave high recovery angles; these were superior to those measured with nanoscale-only features. The results also showed that a large degree of reversible switching of surface hydrophobicity was occurring. Table 19 presents a summary of recovery angles of dual-scale features having a PDMS coating. Recovery angle is given in degrees (°).

TABLE 19

| | Dense Line- | Dense Line- | Dense Line- |
|---|---|---|---|
| Name | 1000 | 600 | 400 |
| Street-20/20 | 0 | 0 | 0 |
| Street-50/50 | 0 | 0 | 0 |
| None | 0 | 11 | 0 |
| Checkerboard 60/20 | 0 | 0 | 0 |
| Checkerboard 40/20 | 0 | 11 | 0 |
| Checkerboard 20/20 | 11 | 0 | 0 |
| Checkerboard 20/40 | 10 | 12 | 11 |
| Checkerboard 20/60 | 0 | 0 | 10 |
| Checkerboard 150/50 | 16 | 20 | 11 |
| Checkerboard 100/50 | 29 | 26 | 0 |
| Checkerboard 50/50 | 19 | 0 | 0 |
| Checkerboard 50/100 | 0 | 0 | 0 |
| Checkerboard 50/150 | 0 | 18 | 0 |
| Line 10/10 | 0 | 0 | 12 |
| Line 20/20 | 18 | 0 | 21 |
| Line 30/30 | 24 | 0 | 23 |
| Line 50/50 | 23 | 16 | 32 |
| Bull's-eye 20/50 | 0 | 0 | 0 |
| Bull's-eye 50/20 | 0 | 0 | 0 |
| Bull's-eye 20/20 | 0 | 13 | 0 |
| Bull's-eye 50/50 | 0 | 0 | 0 |

Recovery Angle of Water on CYTOP-Coated Dual-Scale Patterns with Dense-Line Nanoscale Features and Various Microscale Features

The recovery angle of water on patterns of dual-scale features coated with CYTOP was measured and compared to a surface coated with CYTOP have only nanoscale features. The results showed that for CYTOP, the recovery angle of water in some cases was only marginally higher relative to a nanoscale-only surface, or in other cases lower than the nanoscale-only surface. The results also showed that combinations of either checkerboard or line microscale features with dense line nanoscale features gave high recovery angles, superior to that measured with only nanoscale features. The results also showed that a large degree of reversible switching of surface hydrophobicity was occurring. Table 20 presents a summary of recovery angles of dual-scale features having a CYTOP coating. Recovery angle is given in degrees (°).

TABLE 20

| | Dense Line- | Dense Line- | Dense Line- |
|---|---|---|---|
| Name | 1000 | 600 | 400 |
| Street-20/20 | 0 | 18 | 19 |
| Street-50/50 | 32 | 32 | 29 |
| None | 49 | 22 | 46 |
| Checkerboard 60/20 | 58 | 24 | 33 |
| Checkerboard 40/20 | 66 | 60 | 56 |
| Checkerboard 20/20 | 42 | 45 | 61 |
| Checkerboard 20/40 | 23 | 28 | 28 |
| Checkerboard 20/60 | 31 | 36 | 29 |
| Checkerboard 150/50 | 55 | 56 | 37 |
| Checkerboard 100/50 | 70 | 78 | 70 |
| Checkerboard 50/50 | 57 | 59 | 71 |
| Checkerboard 50/100 | 39 | 40 | 43 |
| Checkerboard 50/150 | 25 | 24 | 29 |
| Line 10/10 | 59 | 60 | 47 |
| Line 20/20 | 59 | 56 | 45 |
| Line 30/30 | 51 | 56 | 55 |
| Line 50/50 | 58 | 37 | 52 |
| Bull's-eye 20/50 | 0 | 0 | 10 |
| Bull's-eye 50/20 | 41 | 29 | 0 |
| Bull's-eye 20/20 | 21 | 22 | 0 |
| Bull's-eye 50/50 | 28 | 34 | 19 |

Recovery Angle of Water on Teflon AF-Coated Dual-Scale Patterns with Dense-Line Nanoscale Features and Various Microscale Features

The recovery angle of water on patterns of dual-scale features coated with Teflon AF was measured and compared with a nanoscale-only surface coated with Teflon AF. The results showed that for Teflon AF, the recovery angle of water was in some cases only marginally higher than for a nanoscale-only surface, or in other cases lower than the nanoscale-only surface. The results also showed that a large degree of reversible switching of surface hydrophobicity was occurring. Table 21 presents a summary of recovery angles of dual-scale features having a Teflon AF coating. Recovery angle is given in degrees (°).

TABLE 21

| | Dense Line- | Dense Line- | Dense Line- |
|---|---|---|---|
| Name | 1000 | 600 | 400 |
| Street-20/20 | 0 | 0 | 0 |
| Street-50/50 | 11 | 15 | 0 |
| None | 59 | 32 | 31 |
| Checkerboard 60/20 | 22 | 34 | 33 |
| Checkerboard 40/20 | 64 | 47 | 48 |
| Checkerboard 20/20 | 43 | 26 | 54 |
| Checkerboard 20/40 | 18 | 20 | 10 |
| Checkerboard 20/60 | 0 | 0 | 0 |
| Checkerboard 150/50 | 37 | 53 | 30 |
| Checkerboard 100/50 | 11 | 64 | 63 |
| Checkerboard 50/50 | 34 | 47 | 24 |
| Checkerboard 50/100 | 14 | 16 | 20 |
| Checkerboard 50/150 | 0 | 13 | 0 |
| Line 10/10 | 50 | 22 | 36 |
| Line 20/20 | 38 | 0 | 43 |
| Line 30/30 | 27 | 34 | 38 |
| Line 50/50 | 24 | 35 | 24 |
| Bull's-eye 20/50 | 0 | 0 | 0 |
| Bull's-eye 50/20 | 0 | 0 | 0 |
| Bull's-eye 20/20 | 0 | 0 | 0 |
| Bull's-eye 50/50 | 0 | 0 | 0 |

Recovery Angle of Water on CYTOP-Coated Dual-Scale Patterns with Dense-Post Nanoscale Features and Various Microscale Features

The recovery angle of water on patterns of dual-scale features coated with CYTOP was measured and compared with a nanoscale-only surface coated with CYTOP. The results showed that for CYTOP, the recovery angle of water was in some cases only marginally higher relative to a nanoscale-only surface, or in other cases lower than the nanoscale-only surface. The results also showed that combinations of either checkerboard or line microscale features with dense post nanoscale features give high recovery angles, superior to that measured with only nanoscale features. The results also showed that a larger degree of reversible switching of surface hydrophobicity was occurring. Table 22 presents a summary of recovery angles of dual-scale features having a CYTOP coating. Recovery angle is given in degrees (°).

TABLE 22

| | Dense Post- | | |
|---|---|---|---|
| Name | 1000 | Dense Post-600 | Dense Post-400 |
| Street-20/20 | 15 | 24 | 10 |
| Street-50/50 | 0 | 23 | 0 |
| None | 0 | 11 | 0 |
| Checkerboard 60/20 | 0 | 0 | 0 |
| Checkerboard 40/20 | 0 | 0 | 0 |
| Checkerboard 20/20 | 0 | 0 | 0 |
| Checkerboard 20/40 | 25 | 20 | 19 |
| Checkerboard 20/60 | 32 | 36 | 33 |
| Checkerboard 150/50 | 0 | 0 | 25 |
| Checkerboard 100/50 | 0 | 0 | 0 |
| Checkerboard 50/50 | 0 | 0 | 0 |
| Checkerboard 50/100 | 18 | 19 | 31 |
| Checkerboard 50/150 | 27 | 22 | 18 |
| Line 10/10 | 0 | 0 | 0 |
| Line 20/20 | 20 | 34 | 42 |
| Line 30/30 | 0 | 30 | 18 |
| Line 50/50 | 0 | 18 | 0 |
| Bull's-eye 20/50 | 17 | 0 | 0 |
| Bull's-eye 50/20 | 0 | 0 | 0 |
| Bull's-eye 20/20 | 0 | 0 | 0 |
| Bull's-eye 50/50 | 0 | 0 | 0 |

Recovery Angle of Water on CYTOP-Coated Dual-Scale Patterns with Dense-Hole Nanoscale Features and Various Microscale Features

The recovery angle of water on patterns of dual-scale features coated with CYTOP was measured and compared with a nanoscale-only surface coated with CYTOP. The results showed that for CYTOP, the recovery angle of water was in some cases only marginally higher relative to a nanoscale-only surface, or in other cases lower than the nanoscale-only surface. The results also showed that combinations of either checkerboard or line microscale features with dense hole nanoscale features give high recovery angles, superior to that measured with only nanoscale features. The results also showed that a larger degree of reversible switching of surface hydrophobicity was occurring. Table 23 presents a summary of recovery angles of dual-scale features having a CYTOP coating. Recovery angle is given in degrees (°).

TABLE 23

| | Dense Hole- | Dense Hole- | Dense Hole- |
|---|---|---|---|
| Name | 1000 | 600 | 400 |

| | | | |
|---|---|---|---|
| Street-20/20 | 22 | 26 | 25 |
| Street-50/50 | 20 | 26 | 25 |
| None | 15 | 0 | 19 |
| Checkerboard 60/20 | 0 | 0 | 0 |
| Checkerboard 40/20 | 0 | 0 | 0 |
| Checkerboard 20/20 | 17 | 21 | 16 |
| Checkerboard 20/40 | 14 | 18 | 22 |
| Checkerboard 20/60 | 29 | 32 | 35 |
| Checkerboard 150/50 | 0 | 0 | 0 |
| Checkerboard 100/50 | 13 | 10 | 15 |
| Checkerboard 50/50 | 0 | 10 | 19 |
| Checkerboard 50/100 | 27 | 20 | 27 |
| Checkerboard 50/150 | 30 | 19 | 27 |
| Line 10/10 | 33 | 35 | 44 |
| Line 20/20 | 50 | 29 | 39 |
| Line 30/30 | 44 | 47 | 48 |
| Line 50/50 | 51 | 39 | 31 |
| Bull's-eye 20/50 | 0 | 0 | 0 |
| Bull's-eye 50/20 | 0 | 0 | 0 |
| Bull's-eye 20/20 | 0 | 0 | 0 |
| Bull's-eye 50/50 | 0 | 0 | 0 |

Recovery Angle of Water on CYTOP-Coated Dual-Scale Patterns with Isolated-Post Nanoscale Features and Various Microscale Features

The recovery angle of water on patterns of dual-scale features coated with CYTOP was measured and compared with a nanoscale-only surface coated with CYTOP. The results showed that for CYTOP, the recovery angle of water was in some cases only marginally higher relative to a nanoscale-only surface, or in other cases lower than the nanoscale-only surface. The results also showed that combinations of either checkerboard or line microscale features with Isolated Post nanoscale features give high recovery angles, superior to that measured with only nanoscale features. The results also showed that a larger degree of reversible switching of surface hydrophobicity was occurring. Table 24 presents a summary of recovery angles of dual-scale features having a CYTOP coating. Recovery angle is given in degrees (°).

TABLE 24

| | Isolated | Isolated | Isolated | Isolated |
|---|---|---|---|---|
| | Post- | Post- | Post- | Post- |
| Name | 1000/2000 | 1000/3000 | 600/1200 | 600/1800 |
| Street-20/20 | 21 | 0 | 0 | 0 |
| Street-50/50 | 12 | 22 | 26 | 29 |
| None | 0 | 0 | 0 | 0 |
| Checkerboard 60/20 | 0 | 0 | 0 | 0 |
| Checkerboard 40/20 | 20 | 34 | 0 | 0 |
| Checkerboard 20/20 | 0 | 0 | 0 | 0 |
| Checkerboard 20/40 | 25 | 18 | 0 | 28 |
| Checkerboard 20/60 | 27 | 24 | 32 | 15 |
| Checkerboard 150/50 | 0 | 0 | 0 | 0 |
| Checkerboard 100/50 | 10 | 0 | 0 | 0 |
| Checkerboard 50/50 | 0 | 0 | 0 | 0 |
| Checkerboard 50/100 | 22 | 33 | 34 | 13 |
| Checkerboard 50/150 | 12 | 11 | 14 | 15 |
| Line 10/10 | 0 | 29 | 0 | 29 |
| Line 20/20 | 32 | 39 | 0 | 43 |
| Line 30/30 | 40 | 32 | 0 | 30 |
| Line 50/50 | 33 | 27 | 37 | 43 |
| Bull's-eye 20/50 | 0 | 0 | 13 | 0 |
| Bull's-eye 50/20 | 10 | 0 | 0 | 0 |

Directional Water Contact Angle on PDMS-Coated Nanoscale Features with Line Microscale Features

The contact angle of water on patterns of dual-scale features coated with PDMS was measured in directions perpendicular and parallel to the Line microscale features. These results showed that the microscale Line features in combination with nanoscale features had an asymmetry with respect to the water contact angle. The contact angle parallel to the Line microscale features was larger than in the perpendicular direction by 20° to 40°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 25 presents a summary of water contact angles of dual-scale features having PDMS coatings. Contact angle is given in degrees (°). The contact angles for line features are asymmetric with the contact angle perpendicular to the line given first and that parallel to the line given second.

TABLE 25

| | Lines | | | |
|---|---|---|---|---|
| Name | 10/10 | 20/20 | 30/30 | 50/50 |
| Dense Line-1000 | 132/123 | 123/146 | 124/159 | 120/151 |
| Dense Line-600 | 144/129 | 127/141 | 123/157 | 123/156 |
| Dense Line-400 | 133/141 | 126/142 | 129/138 | 136/147 |
| Dense Post-1000 | 134/152 | 134/156 | 131/156 | 130/155 |
| Dense Post-600 | 158/140 | 127/156 | 131/158 | 126/154 |
| Dense Post-400 | 150/162 | 155/161 | 151/162 | 139/162 |
| Dense Hole-1000 | 128/150 | 123/153 | 120/154 | 121/152 |
| Dense Hole-600 | 130/156 | 123/148 | 121/134 | 122/154 |
| Dense Hole-400 | 128/156 | 125/157 | 122/150 | 122/151 |
| Isolated Post- | 149/157 | 119/155 | 116/144 | 116/145 |
| 1000/2000 | | | | |
| Isolated Post- | 116/135 | 111/125 | 112/116 | 113/109 |
| 1000/3000 | | | | |
| Isolated Post-600/1200 | 148/161 | 129/156 | 125/161 | 126/161 |
| Isolated Post-600/1800 | 114/138 | 113/122 | 110/130 | 113/120 |

Directional Water Contact Angle on CYTOP-Coated Nanoscale Features with Line Microscale Features

The contact angle of water on patterns of dual-scale features coated with CYTOP was measured in directions perpendicular and parallel to the Line microscale features. These results showed that the microscale Line features in combination with nanoscale features had an asymmetry with respect to the water contact angle. In addition, some combinations of nanoscale and microscale features had larger asymmetry than the microscale line features alone. The contact angle parallel to the Line microscale features was larger than in the perpendicular direction by 20° to 30°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 26 presents a summary of water contact angles of dual-scale features having CYTOP coatings. Contact angle is given in degrees (°). The contact angles for line features are asymmetric with the contact angle perpendicular to the line given first and that parallel to the line given second.

TABLE 26

| | Lines | | | |
|---|---|---|---|---|
| Name | 10/10 | 20/20 | 30/30 | 50/50 |
| No Nano Feature | 135/156 | 133/155 | 136/152 | 134/149 |
| Dense Line-1000 | 142/155 | 147/151 | 146/147 | 148/150 |
| Dense Line-600 | 149/155 | 151/156 | 148/150 | 147/151 |
| Dense Line-400 | 136/154 | 151/159 | 133/160 | 130/152 |
| Dense Post-1000 | 159/157 | 158/158 | 138/151 | 138/154 |
| Dense Post-600 | 162/157 | 163/158 | 138/155 | 153/157 |
| Dense Post-400 | 162/163 | 135/154 | 134/137 | 153/161 |
| Dense Hole-1000 | 133/149 | 136/149 | 135/149 | 136/144 |
| Dense Hole-600 | 137/155 | 136/156 | 136/141 | 133/148 |
| Dense Hole-400 | 136/148 | 135/157 | 134/156 | 137/151 |
| Isolated Post- | 138/156 | 141/144 | 146/140 | 143/152 |
| 1000/2000 | | | | |
| Isolated Post- | 118/132 | 119/118 | 118/123 | 119/126 |
| 1000/3000 | | | | |
| Isolated Post-600/1200 | 153/151 | 151/141 | 146/136 | 139/162 |
| Isolated Post-600/1800 | 124/128 | 117/125 | 117/124 | 116/132 |

Directional Water Contact Angle on Teflon AF-Coated Nanoscale Features with Line Microscale Features

The contact angle of water on patterns of dual-scale features coated with Teflon AF was measured in directions perpendicular and parallel to the Line microscale features. These results showed that the microscale Line features in combination with nanoscale features had an asymmetry with respect to the water contact angle. In addition, some combinations of nanoscale and microscale features had larger asymmetry than the microscale line features alone. The contact angle parallel to the Line microscale features was larger than in the perpendicular direction by 10° to 20°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 27 presents a summary of water contact angles of dual-scale features having CYTOP coatings. Contact angle is given in degrees (°). The contact angles for line features are asymmetric with the contact angle perpendicular to the line given first and that parallel to the line given second.

TABLE 27

| | Lines | | | |
|---|---|---|---|---|
| Name | 10/10 | 20/20 | 30/30 | 50/50 |
| No Nano Feature | 140/155 | 138/157 | 136/151 | 154/146 |
| Dense Line-1000 | 150/155 | 150/151 | — | 139/149 |
| Dense Line-600 | 153/153 | 151/154 | — | 153/152 |
| Dense Line-400 | 155/160 | 141/157 | — | 145/165 |
| Dense Post-1000 | 163/157 | 161/157 | — | 156/159 |
| Dense Post-600 | 162/158 | 162/159 | — | 165/159 |
| Dense Post-400 | 166/158 | 149/163 | — | 142/160 |
| Dense Hole-1000 | 141/160 | 140/155 | — | 136/139 |
| Dense Hole-600 | 141/153 | 137/157 | — | 140/152 |
| Dense Hole-400 | 139/154 | 137/146 | — | 139/152 |
| Isolated Post- | 158/160 | 163/160 | — | 147/158 |
| 1000/2000 | | | | |
| Isolated Post- | 140/153 | 126/138 | — | 126/134 |
| 1000/3000 | | | | |
| Isolated Post-600/1200 | 160/163 | 164/163 | — | 150/163 |
| Isolated Post-600/1800 | 153/145 | 153/163 | — | 146/157 |

Water Contact Angle of PDMS-Coated Dual-Scale Patterns with Dense Line Nanoscale Features

The contact angle of water on patterns of dual-scale features coated with PDMS was measured in directions both perpendicular and parallel to the Line nanoscale features. These results showed that the nanoscale Line features in combination with some microscale features had an asymmetry with respect to the water contact angle. The contact angle parallel to the Line nanoscale features was larger then the contact angle in the perpendicular direction by 20° to 40°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 28 presents a summary of water contact angles of dual-scale features having PDMS coatings. Contact angle is given in degrees (°). The contact angles for line features are asymmetric with the contact angle perpendicular to the line given first and that parallel to the line given second.

TABLE 28

| | | | Dense |
|---|---|---|---|
| Name | Dense Line-1000 | Dense Line-600 | Line-400 |
| Street-20/20 | 126/104 | 123/103 | 149/11 |
| Street-50/50 | 111/102 | 144/106 | 108/97 |
| None | 108/117 | 113/116 | 113/115 |
| Checkerboard 60/20 | 116/137 | 116/113 | 117/129 |
| Checkerboard 40/20 | 135/135 | 136/130 | 135/127 |
| Checkerboard 20/20 | 145/144 | 151/133 | 145/138 |
| Checkerboard 20/40 | 113/103 | 112/99 | 113/101 |
| Checkerboard 20/60 | 111/110 | 110/107 | 110/100 |
| Checkerboard 150/50 | 130/124 | 136/129 | 113/110 |
| Checkerboard 100/50 | 136/133 | 137/134 | 137/131 |
| Checkerboard 50/50 | 146/138 | 147/139 | 145/130 |
| Checkerboard 50/100 | 112/103 | 113/102 | 111/106 |
| Checkerboard 50/150 | 107/104 | 109/109 | 106/104 |
| Line 10/10 | 132/123 | 144/129 | 133/141 |
| Line 20/20 | 123/146 | 127/141 | 126/142 |
| Line 30/30 | 124/159 | 123/157 | 129/138 |
| Line 50/50 | 120/151 | 123/156 | 136/147 |
| Bull's-eye 20/50 | 144/145 | 149/141 | 148/140 |
| Bull's-eye 50/20 | 142/140 | 147/135 | 135/143 |
| Bull's-eye 20/20 | 143/142 | 148/144 | 141/144 |

Water Contact Angle of CYTOP-Coated Dual-Scale Patterns with Dense Line Nanoscale Features

The contact angle of water on patterns of dual-scale features coated with CYTOP was measured in directions both perpendicular and parallel to the Line nanoscale features. These results showed that the nanoscale Line features in combination with some microscale features had an asymmetry with respect to the water contact angle. The contact angle parallel to the Line nanoscale features was larger then the contact angle in the perpendicular direction by 15° to 30°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 29 presents a summary of water contact angles of dual-scale features having CYTOP coatings. Contact angle is given in degrees (°). The contact angles for line features are asymmetric with the contact angle perpendicular to the line given first and that parallel to the line given second.

TABLE 29

| | | | Dense |
|---|---|---|---|
| Name | Dense Line-1000 | Dense Line-600 | Line-400 |
| Street-20/20 | 125/113 | 124/127 | 124/125 |
| Street-50/50 | 120/121 | 121/117 | 127/108 |
| None | 137/147 | 123/130 | 127/142 |
| Checkerboard 60/20 | 139/143 | 142/143 | 134/128 |
| Checkerboard 40/20 | 142/151 | 145/151 | 146/148 |
| Checkerboard 20/20 | 141/149 | 144/152 | 144/154 |
| Checkerboard 20/40 | 124/122 | 124/123 | 126/112 |
| Checkerboard 20/60 | 118/116 | 120/120 | 120/119 |
| Checkerboard 150/50 | 152/146 | 155/149 | 154/140 |
| Checkerboard 100/50 | 140/140 | 146/146 | 144/152 |
| Checkerboard 50/50 | 150/149 | 156/150 | 154/157 |
| Checkerboard 50/100 | 120/117 | 121/118 | 120/119 |
| Checkerboard 50/150 | 118/110 | 120/115 | 118/111 |
| Line 10/10 | 142/155 | 149/155 | 136/154 |
| Line 20/20 | 147/151 | 151/156 | 151/159 |
| Line 30/30 | 146/147 | 148/150 | 133/160 |
| Line 50/50 | 148/150 | 147/151 | 130/152 |
| Bull's-eye 20/50 | 154/136 | 155/146 | 154/156 |
| Bull's-eye 50/20 | 147/153 | 156/152 | 139/151 |
| Bull's-eye 20/20 | 146/150 | 157/152 | 152/150 |
| Bull's-eye 50/50 | 148/149 | 153/154 | 150/146 |

Water Contact Angle of Teflon AF-Coated Dual-Scale Patterns with Dense Line Nanoscale Features

The contact angle of water on patterns of dual-scale features coated with Teflon AF was measured in directions both perpendicular and parallel to the Line nanoscale features. These results showed that the nanoscale Line features in combination with some microscale features had an asymmetry with respect to the water contact angle. The contact angle parallel to the Line nanoscale features was larger then the contact angle in the perpendicular direction by 15° to 20°. The results also showed that there was a directional increase in hydrophobicity of the surface. Accordingly, the surface can have greater liquid or water flow or movement parallel to the direction of the lines. Liquid or water adhesion can be greater in a direction perpendicular to the lines. Table 30 presents a summary of water contact angles of dual-scale features having Teflon AF coatings. Contact angle is given in degrees (°). The contact angles for line features are asymmetric with the contact angle perpendicular to the line given first and that parallel to the line given second.

TABLE 30

| | | | Dense |
|---|---|---|---|
| Name | Dense Line-1000 | Dense Line-600 | Line-400 |
| Street-20/20 | 129/139 | 131/135 | 131/134 |
| Street-50/50 | 125/131 | 131/127 | 124/120 |
| None | 136/151 | 145/155 | 140/151 |
| Checkerboard 60/20 | 143/153 | 147/154 | 148/153 |
| Checkerboard 40/20 | 142/150 | 148/152 | 147/156 |
| Checkerboard 20/20 | 143/144 | 147/148 | 149/153 |
| Checkerboard 20/40 | 131/118 | 132/130 | 131/127 |
| Checkerboard 20/60 | 126/115 | 128/121 | 126/120 |
| Checkerboard 150/50 | 150/154 | 157/153 | 152/159 |
| Checkerboard 100/50 | 144/154 | 150/148 | 147/155 |
| Checkerboard 50/50 | 149/151 | 155/153 | 151/155 |
| Checkerboard 50/100 | 124/122 | 128/125 | 128/123 |
| Checkerboard 50/150 | 125/125 | 124/122 | 127/122 |
| Line 10/10 | 150/155 | 153/153 | 155/160 |
| Line 20/20 | 150/151 | 151/154 | 141/157 |
| Line 50/50 | 139/149 | 153/152 | 145/165 |
| Bull's-eye 20/50 | 157/154 | 159/142 | 156/160 |
| Bull's-eye 50/20 | 151/153 | 158/147 | 152/155 |
| Bull's-eye 20/20 | 145/160 | 158/154 | 148/156 |
| Bull's-eye 50/50 | 150/145 | 159/156 | 154/156 |

### Slide Angle on Microscale-Only Pattern

Table 31 presents a summary of the slide angles of microscale-only features coated with either CYTOP, or Teflon AF. Slide angle is given in degrees (°). The slide angle for the line features are asymmetric and reported as parallel with lines/perpendicular to lines.

TABLE 31

| Name | CYTOP | Teflon AF |
|---|---|---|
| Street-20/20 | 41 | 39 |
| Street-50/50 | 33 | 31 |
| None | 32 | 29 |
| Checkerboard 60/20 | 29 | 37 |
| Checkerboard 40/20 | 30 | 37 |
| Checkerboard 20/20 | 28 | 33 |
| Checkerboard 20/40 | 30 | >45 |
| Checkerboard 20/60 | 25 | >45 |
| Checkerboard 150/50 | 35 | 42 |
| Checkerboard 100/50 | 33 | 36 |
| Checkerboard 50/50 | 32 | >45 |
| Line 10/10 | 9/20 | 25/12 |
| Line 50/50 | 8/26 | 9/36 |
| Bull's-eye 20/50 | 17 | |
| Bull's-eye 50/20 | 29 | |
| Bull's-eye 20/20 | 23 | |
| Bull's-eye 50/50 | 24 | |

### Slide Angle on Nanoscale-Only Patterns

Table 32 presents a summary of the slide angles of nanoscale-only features coated with either PDMS, CYTOP, or Teflon AF. Slide angle is given in degrees (°). The slide angle for the dense line features are asymmetric and reported as parallel with lines/perpendicular to lines.

TABLE 32

| Name | PDMS | CYTOP | Teflon AF |
|---|---|---|---|
| Dense Line-1000 | >45/P | 18/>45 | 11/19 |
| Dense Line-600 | >45/P | 35/>45 | 8/14 |
| Dense Line-400 | >45/P | 30/>45 | 8/11 |
| Dense Post-1000 | P | 16 | 10 |
| Dense Post-600 | P | >45 | 8 |
| Dense Post-400 | P | 10 | 4 |
| Dense Hole-1000 | P | | 41 |
| Isolated Post- | P | 5 | 5 |
| 1000/2000 | | | |
| Isolated Post- | P | P | 5 |
| 1000/3000 | | | |
| Isolated Post- | 9 | 9 | 4 |
| 600/1200 | | | |
| Isolated Post- | P | P | 4 |
| 600/1800 | | | |

Slide Angle of CYTOP-Coated Dual-Scale Patterns with Checkerboard Microscale Features

Table 33 presents a summary of the slide angles of a water drop on dual-scale features having CYTOP coatings. Slide angle is given in degrees (°). The slide angle for the dense line features are asymmetric and reported as parallel with lines/perpendicular to lines. The combination of checker board 60/20, 40/20, or 20/20 with the dense post nanoscale features had the lowest slide angle.

TABLE 33

| | Checkerboard | | | | |
|---|---|---|---|---|---|
| Name | 60/20 | 40/20 | 20/20 | 20/40 | 20/60 |
| Dense Line-1000 | 14/18 | 14/20 | 17/19 | >45/>45 | 42/>45 |
| Dense Line-600 | 7/16 | 19/28 | 12/14 | >45/>45 | 42/P |
| Dense Line-400 | 6/10 | 14/21 | 12/20 | >45/P | >45/30 |
| Dense Post-1000 | 7 | 10 | 9 | >45 | >45 |
| Dense Post-600 | 4 | 7 | 14 | >45 | 36 |
| Dense Post-400 | 5 | 10 | 22 | >45 | 38 |
| Dense Hole-1000 | 38 | P | P | P | >45 |
| Isolated Post- | 2 | P | P | P | >45 |
| 1000/2000 | | | | | |
| Isolated Post- | P | P | >45 | >45 | >45 |
| 1000/3000 | | | | | |
| Isolated Post-600/1200 | 2 | 3 | P | P | >45 |
| Isolated Post-600/1800 | P | P | P | >45 | >45 |

Slide Angle of CYTOP-Coated Dual-Scale Patterns with Checkerboard Microscale Features

Table 34 presents a summary of the slide angles of a water drop on dual-scale features having CYTOP coatings. Slide angle is given in degrees (°). The slide angle for the dense line features are asymmetric and reported as parallel with lines/perpendicular to lines. The combination of checker board 100/50, or 50/50, with the dense post nanoscale features had the lowest slide angle.

TABLE 34

| | Checkerboard | | | | |
|---|---|---|---|---|---|
| Name | 150/50 | 100/50 | 50/50 | 50/100 | 50/150 |
| Dense Line-1000 | 17/29 | 17/P | 13/>45 | >45/>45 | >45/>45 |
| Dense Line-600 | 21/30 | 11/13 | 11/23 | 30/>45 | >45/>45 |
| Dense Line-400 | >45/P | 9/12 | 10/29 | 29/>45 | 43/>45 |
| Dense Post-1000 | P | 10 | 8 | >45 | P |
| Dense Post-600 | 33 | 8 | 17 | >45 | >45 |
| Dense Post-400 | 38 | 19 | 2 | >45 | >45 |
| Dense Hole-1000 | P | >45 | >45 | >45 | >45 |
| Isolated Post- | 11 | 9 | P | >45 | >45 |
| 1000/2000 | | | | | |
| Isolated Post- | P | >45 | P | 29 | >45 |
| 1000/3000 | | | | | |
| Isolated Post-600/1200 | 8 | P | P | >45 | >45 |
| Isolated Post-600/1800 | P | P | P | >45 | P |

Slide Angle of Teflon AF-Coated Dual-Scale Patterns with Checkerboard Microscale Features

Table 35 presents a summary of the slide angles of a water drop on dual-scale features having Teflon AF coatings. Slide angle is given in degrees (°). The slide angle for the dense line features are asymmetric and reported as parallel with lines/perpendicular to lines. The combination of checker board 60/20, 40/20, or 20/20 with the dense post nanoscale features, Isolated Post nanoscale features and dense line nanoscale features had the lowest slide angle.

TABLE 35

| | Checkerboard | | | | |
|---|---|---|---|---|---|
| Name | 60/20 | 40/20 | 20/20 | 20/40 | 20/60 |
| Dense Line-1000 | 12/31 | 11/18 | 14/16 | P/P | >45/>45 |
| Dense Line-600 | 11/13 | 10/8 | 9/7 | >45/P | 37/P |
| Dense Line-400 | 10/13 | 8/9 | 7/11 | P/P | >45/34 |
| Dense Post-1000 | 9 | 7 | 7 | 32 | 33 |
| Dense Post-600 | 7 | 5 | 6 | 34 | 32 |
| Dense Post-400 | 4 | 2 | 3 | 31 | 33 |
| Isolated Post- | 6 | 4 | 5 | 35 | 33 |
| 1000/2000 | | | | | |
| Isolated Post- | >45 | >45 | P | >36 | 40 |
| 1000/3000 | | | | | |
| Isolated Post-600/1200 | 5 | 18 | 4 | 33 | 32 |
| Isolated Post-600/1800 | 3 | 5 | 3 | 38 | 36 |

Slide Angle of PDMS-Coated Dual-Scale Patterns with Checkerboard Microscale Features

Table 36 presents a summary of the slide angles of a water drop on dual-scale features having PDMS coatings. Slide angle is given in degrees (°). The slide angle for the dense line features are asymmetric and reported as parallel with lines/perpendicular to lines. The combination of checkerboard 60/20, 40/20, or 20/20 with the dense post nanoscale features, and Isolated Post-600/1200 nanoscale feature had the lowest slide angle.

TABLE 36

| | Checkerboard | | |
|---|---|---|---|
| Name | 60/20 | 40/20 | 20/20 |
| Dense Line-1000 | P/P | >45/>45 | P/P |
| Dense Line-600 | P/P | P/P | P/P |
| Dense Line-400 | >45/>45 | P/P | 40/33 |
| Dense Post-1000 | 25 | 18 | 11 |
| Dense Post-600 | 17 | 20 | 10 |
| Dense Post-400 | 26 | 7 | 17 |
| Isolated Post- | P | P | P |
| 1000/2000 | | | |
| Isolated Post- | >45 | P | P |
| 1000/3000 | | | |
| Isolated Post-600/1200 | 8 | 7 | P |
| Isolated Post-600/1800 | >45 | >45 | P |

Slide Angle of CYTOP-Coated Dual-Scale Patterns with Line Microscale Features

Table 37 presents a summary of the slide angles of a water drop on dual-scale features having CYTOP coatings. Slide angle is given in degrees (°). The slide angle for the line features are asymmetric and reported as parallel with lines/perpendicular to lines. A single reported measurement is parallel with lines. The combination of Lines 10/10, 20/20, or 30/30 with the dense post nanoscale features and dense line nanoscale features produce the lowest slide angles.

TABLE 37

Lines

| Name | 10/10 | 20/20 | 30/30 | 50/50 |
|---|---|---|---|---|
| Dense Line-1000 | 15/22 | 11/12 | 10/19 | 9/>45 |
| Dense Line-600 | 10/14 | 6/11 | 7/36 | 9/36 |
| Dense Line-400 | 23/33 | 13/13 | 6/18 | 17/17 |
| Dense Post-1000 | 14/20 | 10 | 15 | 11/21 |
| Dense Post-600 | 9/7 | 8 | 17 | 12/5 |
| Dense Post-400 | 36/>45 | 13 | 34 | 8/25 |
| Dense Hole-1000 | 25/>45 | 27 | 24 | 25/45 |
| Isolated Post- | P | 22 | 8 | 31/>45 |
| 1000/2000 | | | | |
| Isolated Post- | P | P | >45 | >45 |
| 1000/3000 | | | | |
| Isolated Post-600/1200 | P | P | >45 | 11/30 |
| Isolated Post-600/1800 | P | P | >45 | P |

Water Contact Angle of CYTOP-Coated Dual-Scale Patterns with Bull's-Eye Microscale Features

Table 38 presents a summary of the slide angles of a water drop on dual-scale features having CYTOP coatings. Slide angle is given in degrees (°). The slide angle for the dense line features are asymmetric and reported as parallel with lines/perpendicular to lines.

TABLE 38

Bull's-eye

| Name | 20/50 | 50/20 | 20/20 | 50/50 |
|---|---|---|---|---|
| Dense Line-1000 | >45/38 | 21/17 | 28/25 | 33/29 |
| Dense Line-600 | >45/P | 18/14 | 18/20 | 22/19 |
| Dense Line-400 | 31/30 | >45/43 | 15/16 | 12/19 |
| Dense Post-1000 | >45 | 28 | >45 | >45 |
| Dense Post-600 | 38 | 19 | 23 | 27 |
| Dense Post-400 | P | 19 | 28 | 38 |
| Dense Hole-1000 | P | P | P | >45 |
| Isolated Post- | P | 21 | 31 | 27 |
| 1000/2000 | | | | |
| Isolated Post- | P | P | P | P |
| 1000/3000 | | | | |
| Isolated Post-600/1200 | >45 | 18 | 29 | 29 |
| Isolated Post-600/1800 | P | P | P | P |

Other embodiments are within the scope of the following claims.

What is claimed is:

1. A surface having reversibly switchable wetting and/or adhesion properties, the surface comprising a plurality of microscale features arranged in a microscale pattern, wherein at least a portion of the microscale features include a plurality of nanoscale features arranged in a nanoscale pattern.

2. The surface of claim 1, wherein the surface is disposed over a substrate.

3. The surface of claim 2, wherein the substrate includes an electrode.

4. The surface of claim 3, wherein the substrate further includes a dielectric layer between the electrode and the surface.

5. The surface of claim 1, wherein the microscale pattern is a first repeating pattern.

6. The surface of claim 5, wherein the first repeating pattern is a street pattern, a checkerboard pattern, a line pattern, or a bull's-eye pattern.

7. The surface of claim 6, wherein the dimensions of the microscale features are between 1 μm and 200 μm.

8. The surface of claim 1, wherein the nanoscale pattern is a second repeating pattern.

9. The surface of claim 8, wherein the second repeating pattern is a line pattern, a post pattern, a hole pattern, or an isolated-post pattern.

10. The surface of claim 9, wherein the dimensions of the nanoscale features are between 10 nm and 3,000 nm.

11. The surface of claim 7, wherein the plurality of nanoscale features occur in a second repeating pattern, wherein the second repeating pattern is a line pattern, a post pattern, a hole pattern, or an isolated-post pattern, and wherein the dimensions of the nanoscale features are between 10 nm and 3,000 nm.

12. The surface of claim 6, wherein the first repeating pattern is a line pattern.

13. The surface of claim 12, wherein the wetting and/or adhesion properties of the surface are different when measured parallel or perpendicular to the line pattern.

14. The surface of claim 9, wherein the second repeating pattern is a line pattern.

15. The surface of claim 14, wherein the wetting and/or adhesion properties of the surface are different when measured parallel or perpendicular to the line pattern.

16. The surface of claim 1, further comprising a coating covering the surface.

17. The surface of claim 16, wherein the coating includes a hydrophobic material, a photoswitchable material, a thermally switchable material, or a chemically switchable material.

18. A method of reversibly altering the liquid adhesion properties of a surface, comprising:
providing a surface including a plurality of microscale features arranged in a microscale pattern, wherein at least a portion of the microscale features include a plurality of nanoscale features arranged in a nanoscale pattern, and
applying an adhesion-altering stimulus to the surface.

19. The method of claim 18, wherein applying the wetting-altering stimulus includes altering a voltage applied to the surface, exposing the surface to light, altering the temperature to which the surface is exposed, altering the pH to which the surface is exposed, or contacting the surface with a wetting-altering composition.

20. A method of reversibly altering the liquid wetting properties of a surface, comprising:
providing a surface including a plurality of microscale features arranged in a microscale pattern, wherein at least a portion of the microscale features include a plurality of nanoscale features arranged in a nanoscale pattern, and
applying a wetting-altering stimulus to the surface.

21. The method of claim 20, wherein applying the wetting-altering stimulus includes altering a voltage applied to the surface, exposing the surface to light, altering the temperature to which the surface is exposed, altering the pH to which the surface is exposed, or contacting the surface with a wetting-altering composition.

22. A method of making a reversibly switchable surface, comprising:
forming, on a surface, a plurality of microscale features arranged in a microscale pattern, wherein at least a portion of the microscale features include a plurality of nanoscale features arranged in a nanoscale pattern.

23. The method of claim 22, wherein forming includes forming, across a microscale area, a plurality of nanoscale features arranged in a nanoscale pattern, and removing a portion of the nanoscale features, wherein removing a portion of the nanoscale features includes forming the plurality of microscale features arranged in a microscale pattern.

24. The method of claim 23, wherein the surface is disposed over a substrate.

25. The method of claim 24, wherein the substrate includes an electrode.

26. The method of claim 22, further comprising covering the surface with a coating.

27. The method of claim 26, wherein the coating includes a hydrophobic material, a photoswitchable material, a thermally switchable material, or a chemically switchable material.

28. A system comprising:
a substrate including an electrically conductive layer;
a surface arranged over the electrically conductive layer, the surface including a plurality of microscale features arranged in a microscale pattern, wherein at least a portion of the microscale features include a plurality of nanoscale features arranged in a nanoscale pattern;
a voltage source connected to the electrically conductive layer; and
a switch between the voltage source and the electrically conductive layer, configured to controllably apply or remove voltage from the electrically conductive layer.
